(19) United States
(12) Patent Application Publication
(10) Pub. No.: US 2024/0110084 A1
(43) Pub. Date: Apr. 4, 2024

(54) Laminates for Cleaning Substrate Surfaces and Methods of Use Thereof

(71) Applicant: 3M INNOVATIVE PROPERTIES COMPANY, St. Paul, MN (US)

(72) Inventors: Uma Rames Krishna Lagudu, Lake Elmo, MN (US); Benjamin R. Coonce, South St. Paul, MN (US); Morgan A. Priolo, Woodbury, MN (US); William Blake Kolb, Stillwater, MN (US); Eric W. Nelson, Stillwater, MN (US)

(21) Appl. No.: 18/253,964

(22) PCT Filed: Dec. 3, 2021
(86) PCT No.: PCT/IB2021/061334

§ 371 Date: May 23, 2023

Related U.S. Application Data
(60) Provisional application No. 63/121,696, filed on Dec. 4, 2020.
(60) Provisional application No. 63/282,428, filed on Nov. 23, 2021.

(51) Int. Cl. C09J 135/02; B08B 7/00; C09J 4/00; C09J 5/00

(52) U.S. Cl. CPC C09J 135/02; B08B 7/0014; C09J 4/00; C09J 5/00; C09J 2433/00; H01L 21/02096

(57) ABSTRACT

The present disclosure provides laminates, which include adhesive materials and methods that allow for the removal of contaminants, e.g. particulate contaminants, from a substrate surface. In one embodiment, the laminates include (i) a substrate with contaminant disposed on its surface, (ii) a liquid, adhesive precursor and (iii) a film layer. The liquid, adhesive precursor is disposed between the substrate and the film layer. In another embodiment, the laminates include (i) a substrate with contaminant disposed on its surface, (ii) a cured adhesive layer and (iii) a film layer. The cured adhesive layer is disposed between the substrate and the film layer. The laminates may be used to remove contaminant from the substrate surface by removal of the film layer and the cured adhesive layer, which entraps the contaminant therein.

### FIELD OF THE DISCLOSURE

The present disclosure relates to laminates that include a liquid, adhesive precursor, laminates containing a cured adhesive layer and methods of use thereof for the cleaning of substrate surfaces.

### BACKGROUND

General methods of cleaning substrate surfaces using polymeric materials are described in, for example, U.S. Pat. Nos. 5,902,678, 6,776,171 and 8,753,712.

### BRIEF DESCRIPTION OF THE FIGURES

The disclosure may be more completely understood in consideration of the following detailed description of various embodiments of the disclosure in connection with the accompanying figures, in which:

FIG. 1A is a schematic cross-sectional diagram of a portion of laminate in accordance with some embodiments of the present disclosure.

FIG. 1B is a schematic cross-sectional diagram of a portion of laminate in accordance with some embodiments of the present disclosure.

FIGS. 2A-2E illustrates a schematic diagram of a method of cleaning a substrate surface in accordance with some embodiments of the present disclosure.

### DETAILED DESCRIPTION

The cleaning of substrate surfaces is important in numerous industrial processes. In many instances, the cleaning technique employed relates to the size and/or type of the contaminant that is on the substrate surface. Frequently, the contaminant to be removed from the substrate surface is a particulate contaminant. Generally, the smaller the particle size of the particulate contaminant, the more difficult it is to remove from the surface. One technology area that requires the cleaning of extremely small particulates from the surface of a substrate is chemical mechanical planarization (CMP) of wafers. During the CMP process, slurries are often used to planarize and/or polish the wafer surface. The size of the particles in the CMP slurries are generally less than 200 nm, more typically less than 100 nm and, even on the order of 50 nm or less. Use of smaller sized particles is generally desirable, as smaller particles typically lead to lower defects, e.g. smaller and/or less scratches, on the wafer surface. After the CMP process, it is often desirable to remove any remaining slurry particles from the wafer surface, prior to the next wafer fabrication step. Current cleaning technology often employs “wet” cleaning processes that may utilize corrosive chemicals, e.g. HF, tetramethyl ammonium hydroxide, H₂SO₄, Hot NH₃, H₂O₂, HNO₃, H₃PO₄, combinations thereof and/or aqueous solutions thereof. However, due to their small particle size, stronger dispersion, capillary and Vanderwaals' forces are involved in retaining the particles at the substrate surface and make it difficult to remove the particles by conventional techniques. Additionally, these ultrafine particles may be surface modified to make them more reactive and allow them to bind to the surface of the substrate that needs to be polished, in order to maintain the desired high CMP polish rates. However, the surface modifications add further difficulties to post CMP wafer cleaning processes. Overall, there is a need for improved cleaning materials and cleaning processes. The present disclosure provides unique adhesive materials, laminates therefrom and corresponding cleaning processes capable of removing particles, e.g. particles on the order of 10s of nanometers in size, from the surface of a substrate.

Unless otherwise indicated, all numbers expressing feature sizes, amounts, and physical properties used in the specification and claims are to be understood as being modified in all instances by the term “about.” Accordingly, unless indicated to the contrary, the numbers set forth are approximations that can vary depending upon the desired properties using the teachings disclosed herein.

The terms “a”, “an”, and “the” are used interchangeably with “at least one” to mean one or more of the elements being described.

The phrase “entraps the particulate contaminant” refers to a cured adhesive layer which is in contact with particulate contaminant, such that the adhesive force between the particulate contaminant and the cured adhesive layer is greater than the adhesive force between the particulate contaminant and a substrate surface, such that upon removal of the adhesive film from the substrate surface, the particulate contaminant remains attached to and/or contained within the adhesive film and is removed from the substrate surface. The adhesive force between the particulate contaminant and the cured adhesive layer includes, but is not limited to, mechanical forces associated with the adhesive encapsulating the particulate contaminant.

The term “liquid” in reference to a liquid, adhesive precursor, means that the adhesive precursor is capable of flowing. Alternatively, the liquid, adhesive precursor may have a viscosity of less than 3500 cP, less than 2000 cP, less than 1000 cP, less than 500 cP, less than 200 cP, less than 100 cP, less than 50 cP or less than 20 cP. In some embodiments, a liquid, adhesive precursor having lower viscosity, which facilitates the coating of at least a portion of a substrate surface and/or the particulate contaminant, may be preferred. The viscosity of the liquid, adhesive precursor may be measured using a rotational viscometer following conventional testing techniques.

The terms “cure”, “curing” and “cured” refer to processes through which a material, e.g. a liquid adhesive precursor, hardens and/or becomes solid. Curing can include processes such as, for example, polymerization, crosslinking, e.g. polymerization and/or crosslinking via an actinic radiation, drying and combinations thereof.

The term “(meth)acrylate” refers to an acrylate, methacrylate, or both.

The term “alkyl” refers to a monovalent group which is a saturated hydrocarbon. The alkyl can be linear, branched, cyclic, or combinations thereof and typically has 1 to 30 carbon atoms. In some embodiments, the alkyl group contains 1 to 30, 1 to 18, 1 to 12, 1 to 10, 1 to 8, 1 to 6, or 1 to 4 carbon atoms. Examples of alkyl groups include, but are not limited to, methyl, ethyl, n-propyl, isopropyl, n-butyl, isobutyl, tert-butyl, n-pentyl, n-hexyl, cyclohexyl, n-heptyl, n-octyl, and 2-ethylhexyl.

The present disclosure provides laminates which include adhesive materials and methods that allow for the removal of contaminants, e.g. particulate contaminants, from a substrate surface. A liquid adhesive precursor is applied to the surface of a substrate which includes contaminant, e.g. particulate contaminant, disposed thereon. The liquid adhesive precursor flows and wets the surface of the substrate as well as the contaminant, i.e. coats the substrate or at least a portion thereof and coats the particulate contaminate or at least a portion thereof. In some embodiments, the liquid, adhesive precursor may partially or completely encapsulate the particulate contaminant. In some embodiments, the liquid, adhesive precursor may be heated to lower its viscosity and/or surface tension to improve flow characteristics and wettability of the substrate surface and/or contaminant surface. A film layer, e.g. polymeric film, is applied to the exposed surface of the liquid, adhesive precursor. At this point, a laminate is formed that includes (i) a substrate with contaminant on its surface, (ii) a liquid, adhesive precursor and (iii) a film layer. The liquid, adhesive precursor is disposed between the substrate and the film layer. In some embodiments, the liquid, adhesive precursor has at least one of (i) a total solubility parameter of no greater than 9.20 (cal/cm³)^{0.5} and (ii) a hydrogen bonding component solubility parameter of greater than 4.50 (cal/cm³)^{0.5}. The liquid, adhesive precursor is then cured, for example, by exposing to actinic radiation, forming a cured adhesive layer having a first major surface in contact with the surface of the substrate and the particulate contaminant and a second major surface in contact with the film layer. The cured adhesive layer is disposed between the substrate and the film layer. The cured adhesive layer entraps the particulate contaminant. At this point, a laminate is formed that includes (i) a substrate with particulate contaminant on its surface, (ii) a cured adhesive layer and (iii) a film layer. In some embodiments, the cured adhesive layer is the reaction product of a liquid, adhesive precursor having at least one of (i) a total solubility parameter of no greater than 9.20 (cal/cm³)^{0.5} and (ii) a hydrogen bonding component solubility parameter of greater than 4.50 (cal/cm³)^{0.5}. The film layer and cured adhesive layer may then be removed from the substrate surface. During removal the contaminant is retained on and/or within the cured adhesive layer and is subsequently removed from the surface of the substrate. Generally, the adhesion between the film layer and the cured adhesive layer may be greater than the adhesion between the cured adhesive layer and the substrate surface and the adhesion between the cured adhesive layer and the contaminant may be greater than the adhesion between the contaminant and the substrate surface. In some embodiments, the peel strength between the cured adhesive layer and substrate is less than the peel strength between the cured adhesive layer and film layer. In some embodiments, the liquid, adhesive precursors and their corresponding cure adhesive layers of the present disclosure may be used to bond two substrates together to form a laminate. In some embodiments, when the mechanical integrity of the cured adhesive layer is sufficient to allow for peeling, i.e. removal from the substrate, the film layer may be omitted from the above described laminates.

The present disclosure further provides laminates which include adhesive materials and methods that allow for the removal of contaminants, e.g. particulate contaminants, from a substrate surface that also includes at least one solvent, e.g. a polar solvent. A liquid, adhesive precursor is applied to the surface of a substrate which contains contaminant, e.g. particulate contaminant, and at least one solvent, e.g. a polar solvent, disposed thereon. The liquid flows and wets the surface of the substrate, the contaminant as well as the solvent. In some embodiments, the liquid, adhesive precursor may be heated to lower its viscosity and/or surface tension to improve flow characteristics and wettability of the substrate surface and/or contaminant surface. In some embodiments, at least a portion of the solvent is absorbed by the liquid, adhesive precursor. A film layer, e.g. polymeric film, is applied to the exposed surface of the liquid, adhesive precursor. At this point, a laminate is formed that includes (i) a substrate with contaminant disposed on its surface, (ii) a liquid, adhesive precursor and (iii) a film layer. The liquid, adhesive precursor is disposed between the substrate and the film layer. In some embodiments, the liquid, adhesive precursor has at least one of (i) a total solubility parameter of no greater than 9.20 (cal/cm³)^{0.5} and (ii) a hydrogen bonding component solubility parameter of greater than 4.50 (cal/cm³)^{0.5}. In some embodiments, the liquid, adhesive precursor is capable of absorbing between 0.5 wt. % and 125 wt. % of the solvent, based on the weight of the liquid, adhesive precursor, while maintaining its ability to be cured. The liquid, adhesive precursor is then cured, for example, by exposing to actinic radiation, forming a cured adhesive layer having a first major surface in contact with the surface of the substrate and the particulate contaminant and a second major surface in contact with the film layer. The cured adhesive layer is disposed between the substrate and the film layer. The cured adhesive layer entraps the particulate contaminant. At this point, a laminate is formed that includes (i) a substrate with particulate contaminant disposed on its surface, (ii) a cured adhesive layer and (iii) a film layer. In some embodiments, the cured adhesive layer is the reaction product of a liquid, adhesive precursor having at least one of (i) a total solubility parameter of no greater than 9.20 (cal/cm³)^{0.5} and (ii) a hydrogen bonding component solubility parameter of greater than 4.50 (cal/cm³)^{0.5}. In some embodiments. the cured adhesive layer includes between 0.5 wt. % and 125 wt. % of the solvent, based on the weight of the cured adhesive layer excluding the polar solvent. The film layer and cured adhesive layer may then be removed from the substrate surface. During removal the contaminant is retained in the cured adhesive layer and is subsequently removed from the surface of the substrate. Generally, the adhesion between the film layer and the cured adhesive layer may be greater than the adhesion between the cured adhesive layer and the substrate surface and the adhesion between the cured adhesive layer and the contaminant may be greater than the adhesion between the contaminant and the substrate surface. In some embodiments, the peel strength between the cured adhesive layer and substrate is less than the peel strength between the cured adhesive layer and film layer. In some embodiments, the liquid, adhesive precursors and their corresponding cure adhesive layers of the present disclosure may be used to bond two substrates together to form a laminate. In some embodiments, when the mechanical integrity of the cured adhesive layer is sufficient to allow for peeling, i.e. removal from the substrate, the film layer may be omitted from the above described laminates.

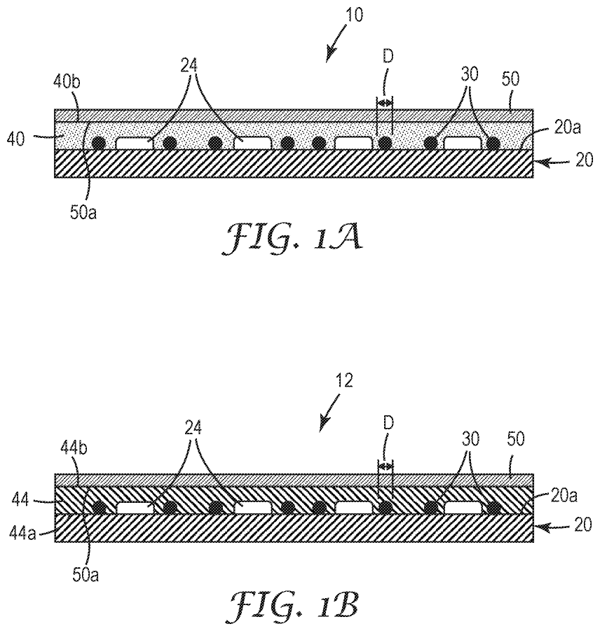

In one embodiment the present disclosure provides a laminate comprising a substrate having a first surface including a particulate contaminant disposed on the first surface; a liquid, adhesive precursor in contact with the first surface of the substrate and the particulate contaminant, wherein the liquid, adhesive precursor is capable of being cured by actinic radiation and; a film layer in contact with the liquid, adhesive precursor. In some embodiments, the liquid, adhesive precursor has at least one of (i) a total solubility parameter of no greater than 9.20 (cal/cm³)^{0.5} and (ii) a hydrogen bonding component solubility parameter of greater than 4.50 (cal/cm³)^{0.5}. A schematic cross-sectional diagram of a laminate 10, according to some embodiments of the present disclosure, is shown in FIG. 1A. Laminate 10 includes substrate 20 having a first surface 20a including particulate contaminant 30 disposed on first surface 20a. First surface 20a of substrate 20 may include at least one, optional, topographical feature 24. Laminate 10 also includes liquid, adhesive precursor 40. Liquid, adhesive precursor 40 is in contact with first surface 20a of substrate 20 and particulate contaminant 30. Liquid, adhesive precursor 40 is capable of being cured, by actinic radiation. Particulate contaminant 30 has a longest dimension, D. Laminate 10 further includes film layer 50 in contact with the liquid, adhesive precursor 40. Generally, major surface 50a of film layer 50 is in contact with liquid, adhesive precursor major surface 40b, and liquid, adhesive precursor major surface 40b is opposite that of first surface 20a of substrate 20.

In some embodiments, laminate 10 may further include a solvent (not shown), e.g. a polar solvent, dispose on at least a portion of the first surface of the substrate. The solvent may be in the form of a continuous layer covering at least 20 percent, at least 30 percent, at least 40 percent, at least 50, at least 60 percent, at least 70 percent at least 80 percent or at least 90% of the area of the first surface of the substrate that is not in contact with particulate contaminant. The solvent may be in the form of a plurality of isolated regions, e.g. a plurality of droplets, on the first surface of the substrate. The plurality of isolated regions of solvent may cover greater than at least 2 percent, greater than at least 5 percent, greater than at least 10 percent, greater than at least 20 percent or greater than at least 30 percent and/or less than at least 90 percent, less than at least 80 percent or less than at least 70 percent of the area of the first surface of the substrate that is not in contact with particulate contaminant. In some embodiments the solvent is a polar solvent. The polar solvent is not particularly limited. The polar solvent includes, but is not limited to water, methanol, ethanol, propanol, isopropanol and combinations thereof.

In some embodiments, the liquid, adhesive precursor is capable of absorbing between 0.5 wt. % and 125 wt. %, between 2 wt. % and 125 wt. % between 5 wt. % and 125 wt. % between 10 wt. % and 125 wt. %, between 25 wt. % and 125 wt. %, between 50 wt. % and 125 wt. % or between 75 wt. % and 125 wt. % of a polar solvent, based on the weight of the liquid (excluding the polar solvent), adhesive precursor, while maintaining its ability to be cured by actinic radiation. In some embodiments the liquid, adhesive precursor is capable of absorbing at least 0.5 wt. %, at least 2 wt. % at least 5 wt. %, at least 10 wt. %, at least 20 wt. % at least 30 wt. %, at least 40 wt. %, at least 50 wt. % or at least 75 wt. % and/or less than 125 wt. %, less than 100 wt. % or less than 80 wt. % of a polar solvent, based on the weight of the liquid, adhesive precursor (excluding the polar solvent), while maintaining its ability to be cured by actinic radiation. In order for the liquid, adhesive precursor to be capable of absorbing polar solvent at the amounts disclosed herein, the composition of the liquid adhesive precursor may be designed to solubilize polar solvent. However, the solubilized polar solvent should have little to no effect on the ability of the liquid, adhesive precursor to be cured into a cured adhesive layer.

Although not to be bound by theory, a solubility parameter approach may be used to define the composition of the liquid, adhesive precursor. The solubility parameter may define the composition of the liquid, adhesive precursor that enables the liquid, adhesive precursors of the present disclosure to absorb polar solvent. There are a variety of different techniques, e.g. group contribution methods, known in the art that may be used to calculate the solubility parameter of a single compound or a mixture of compounds. Throughout this disclosure when the phrase “total solubility parameter” is used, the solubility parameter is determined based on the group contribution calculations as defined by P. A. Small in the J. Appl. Chem., 3, 71 (1953). Throughout this disclosure when the phrase “hydrogen bonding component solubility parameter” is used, the solubility parameter is determined based on the hydrogen bonding component of the group contribution calculations as defined by Hansen in “Hansen Solubility Parameters: A User's Handbook”, CRC Press, Inc., Boca Raton FL, 1999. The hydrogen bonding component solubility parameter may be calculated using a software program available under the trade designation “Molecular Modeling Pro Plus”, from Norgwyn Montgomery Software, Inc., North Wales, Pennsylvania. If a mixture of compounds is used to form the liquid, adhesive precursor, the solubility parameter of each compound is calculated individually and then the solubility parameter, e.g. total solubility parameter (Total SP) and/or hydrogen bonding component solubility parameter (H-Bonding SP), of the liquid, adhesive precursor (mixture) is defined as the sum of the products of the solubility parameter of each compound times its mole fraction in the mixture.

In some embodiments, the liquid, adhesive precursor has a total solubility parameter of no greater than 9.20 (cal/cm³)^{0.5}, no greater than 9.10 (cal/cm³)^{0.5}, no greater than 9.00 (cal/cm³)^{0.5} or no greater than 8.90 (cal/cm³)^{0.5} and/or greater than 8.00 (cal/cm³)^{0.5}, greater than 8.20 (cal/cm³)^{0.5}, greater than 8.40 (cal/cm³)^{0.5}, greater than 8.60 (cal/cm³)^{0.5} or greater than 8.70 (cal/cm³)^{0.5}; and/or the liquid, adhesive precursor has a hydrogen bonding component solubility parameter of greater than 4.50 (cal/cm³)^{0.5}, greater than 5.00 (cal/cm³)^{0.5}, greater than 5.4 (cal/cm³)^{0.5} or greater than 5.60 (cal/cm³)^{0.5} and/or less than 11.00 (cal/cm³)^{0.5}, less than 9.00 (cal/cm³)^{0.5}, less than 7.00 (cal/cm³)^{0.5}, less than 6.50 (cal/cm³)^{0.5} or less than 6.00 (cal/cm³)^{0.5}. In some embodiments, the total solubility parameter is between 9.20 (cal/cm³)^{0.5} and 8.00 (cal/cm³)^{0.5}, between 9.20 (cal/cm³)^{0.5} and 8.20 (cal/cm³)^{0.5}, between 9.20 (cal/cm³)^{0.5} and 8.40 (cal/cm³)⁵, between 9.20 (cal/cm³)⁵ and 8.60 (cal/cm³)^{0.5}, between 9.10 (cal/cm³)^{0.5} and 8.00 (cal/cm³)^{0.5}, between 9.10 (cal/cm³)^{0.5} and 8.20 (cal/cm³)^{0.5}, between 9.10 (cal/cm³)^{0.5} and 8.40 (cal/cm³)^{0.5} or between 9.10 (cal/cm³)⁰ and 8.60 (cal/cm³)^{0.5}; and/or the hydrogen bonding component solubility parameter is between 4.5 (cal/cm³)^{0.5} and 11.00 (cal/cm³)^{0.5}, between 4.50 (cal/cm³)^{0.5} and 9.00 (cal/cm³)^{0.5}, between 4.50 (cal/cm³)^{0.5} and 7.00 (cal/cm³)^{0.5}, between 4.50 (cal/cm³)^{0.5} and 6.50 (cal/cm³)^{0.5}, between 4.50 (cal/cm³)^{0.5} and 6.00 (cal/cm³)^{0.5}, between 5.00 (cal/cm³)^{0.5} and 11.00 (cal/cm³)^{0.5}, between 5.00 (cal/cm³)^{0.5} and 9.00 (cal/cm³)^{0.5}, between 5.00 (cal/cm³)^{0.5} and 7.00 (cal/cm³)^{0.5}, between 5.00 (cal/cm³)^{0.5} and 6.50 (cal/cm³)^{0.5}, between 5.00 (cal/cm³)^{0.5} and 6.00 (cal/cm³)^{0.5}, between 5.40 (cal/cm³)^{0.5} and 11.00 (cal/cm³)^{0.5}, between 5.40 (cal/cm³)^{0.5} and 9.00 (cal/cm³)^{0.5}, between 5.40 (cal/cm³)^{0.5} and 7.00 (cal/cm³)^{0.5}, between 5.40 (cal/cm³)^{0.5} and 6.50 (cal/cm³)^{0.5}, between 5.40 (cal/cm³)^{0.5} and 6.00 (cal/cm³)^{0.5}, between 5.60 (cal/cm³)^{0.5} and 11.00 (cal/cm³)^{0.5}, between 5.60 (cal/cm³)^{0.5} and 9.00 (cal/cm³)^{0.5}, between 5.60 (cal/cm³)^{0.5} and 7.00 (cal/cm³)^{0.5}, between 5.60 (cal/cm³)^{0.5} and 6.50 (cal/cm³)^{0.5} or between 5.60 (cal/cm³)^{0.5} and 6.00 (cal/cm³)^{0.5}.

In some embodiments, the liquid, adhesive precursor is a single-phase solution. In some embodiments the liquid, adhesive precursor includes at least 0.5 wt. %, at least 2 wt. % at least 5 wt. %, at least 10 wt. %, at least 20 wt. % at least 30 wt. %, at least 40 wt. % at least 50 wt. %, or at least 75 wt. % and/or less than 125 wt. %, less than 100 wt. % or less than 80 wt. % of a polar solvent, based on the weight of the liquid, adhesive precursor excluding the polar solvent, while maintaining its ability to be cured by actinic radiation. In some embodiments the liquid, adhesive precursor includes at least 0.5 wt. %, at least 2 wt. % at least 5 wt. %, at least 10 wt. %, at least 20 wt. % at least 30 wt. % or at least 40 wt. % at least 50 wt. %, or at least 75 wt. % and/or less than 125 wt. %, less than 100 wt. % or less than 75 wt. % of a polar solvent, based on the weight of the liquid, adhesive precursor excluding the polar solvent, while maintaining its ability to be cured by actinic radiation, and the liquid, adhesive precursor is a single-phase solution. In some embodiments, e.g. wherein the liquid, adhesive precursor absorbs polar solvent, it is important that the liquid, adhesive be a single-phase solution or, if phase separation occurs, it occurs to a minor degree so as to not cause significant opacity in the liquid, adhesive precursor, such that curing by actinic radiation may occur. A two-phase liquid, adhesive precursor solution, i.e. a phase separated liquid, adhesive precursor, may result in an opaque liquid, adhesive precursor that is capable of blocking and/or scattering the actinic radiation used for curing. This may limit the depth of cure and inhibit the liquid, adhesive precursor from fully curing (inhibiting the formation of the cured adhesive layer), thereby degrading the improperly cured adhesive layer's ability to perform as designed, e.g. entrap particulate contaminant such that it may be removed from the substrate surface. If the liquid, adhesive precursor does not fully cure, uncured or partially cured liquid adhesive precursor may remain on the substrate surface, after the film layer and cured adhesive layer is removed from the substrate. This uncured or partially cured liquid adhesive precursor which remains on the substrate surface may hinder the removal of particulate contaminant, which is undesirable. “Fully curing” and “fully cure” means that the liquid, adhesive precursor has sufficient depth of cure and extent of cure to be removed cleanly from the substrate, i.e. there is no cured adhesive layer residue and/or liquid, adhesive precursor remaining on the substrate surface.

The composition of the liquid, adhesive precursor is not particularly limited. The liquid, adhesive precursor is capable of being cured and the curing technique is not particularly limited and may include, for example, curing by actinic radiation, thermal curing, e-beam curing and combinations thereof. Actinic radiate may include electromagnetic radiation in the UV, e.g. 100 to 400 nm, and visible range, e.g. 400 to 700 nm, of the electromagnetic radiation spectrum. Due to its rapid cure characteristics, the curing of the liquid, adhesive precursor by actinic radiation may be preferred. The liquid, adhesive precursor may include monomers, oligomers and/or polymers that can be cured by conventional free radical mechanisms.

In some embodiments, the liquid, adhesive precursor includes one or more (meth)acrylates. The (meth)acrylate may be at least one of monomeric, oligomeric and polymeric. The (meth)acrylate may be polar, non-polar or mixtures thereof. Non-polar (meth)acrylate may include alkyl meth(acrylate). Useful non-polar (meth)acrylate include, but are not limited to, methyl (meth)acrylate, ethyl (meth)acrylate, n-propyl (meth)acrylate, isopropyl (meth)acrylate, n-butyl (meth)acrylate, isobutyl (meth)acrylate, tert-butyl (meth)acrylate, n-pentyl (meth)acrylate, iso-pentyl (meth)acrylate (i.e., iso-amyl (meth)acrylate), 3-pentyl (meth)acrylate, 2-methyl-1-butyl (meth)acrylate, 3-methyl-1-butyl (meth)acrylate, stearyl (meth)acrylate, phenyl (meth)acrylate, n-hexyl (meth)acrylate, iso-hexyl (meth)acrylate, cyclohexyl (meth)acrylate, 2-methyl-1-pentyl (meth)acrylate, 3-methyl-1-pentyl (meth)acrylate, 4-methyl-2-pentyl (meth)acrylate, 2-ethyl-1-butyl (meth)acrylate, 2-methy-1-hexyl (meth)acrylate, 3,5,5-trimethyl-1-hexyl (meth)acrylate, cyclohexyl (meth)acrylate, 3-heptyl (meth)acrylate, benzyl (meth)acrylate, n-octyl (meth)acrylate, iso-octyl (meth)acrylate, 2-octyl (meth)acrylate, 2-ethyl-1-hexyl (meth)acrylate, n-decyl (meth)acrylate, iso-decyl (meth)acrylate, isobornyl (meth)acrylate, 2-propylheptyl (meth)acrylate, isononyl (meth)acrylate, isophoryl (meth)acrylate, n-dodecyl (meth)acrylate (i.e., lauryl (meth)acrylate), n-tridecyl (meth)acrylate, iso-tridecyl (meth)acrylate, 3,7-dimethyl-octyl (meth)acrylate, and any combinations or mixtures thereof. Combinations of non-polar (meth)acrylates may be used.

Polar (meth)acrylate include, but are not limited to, 2-hydroxyethyl (meth)acrylate; poly(alkoxyalkyl) (meth)acrylates including 2-(2-ethoxyethoxy)ethyl (meth)acrylate, 2-ethoxyethyl (meth)acrylate, 2-methoxyethoxyethyl (meth)acrylate, 2-methoxyethyl methacrylate; alkoxylated (meth)acrylates (e.g. ethoxylated and propoxylated (meth)acrylate), and mixtures thereof. The alkoxylated (meth)acrylates may be monofunctional, difunctional, trifunctional or have higher functionality. Ethoxylated acrylates include, but are not limited to, ethoxylated (3) trimethylolpropanc triacrylate (available under the trade designation “SR454”, from Sartomer, Exton, Pennsylvania), ethoxylated (6) trimethylolpropane triacrylate (available under the trade designation “SR499”, from Sartomer), ethoxylated (6) trimethylolpropane triacrylate (available under the trade designation “MIRAMER M3160” from Miwon North America Inc., Exton Pennsylvania), ethoxylated (9) trimethylolpropane triacrylate (available under the trade designation “SR502”, from Sartomer), ethoxylated (15) trimethylolpropane triacrylate (available under the trade designation “SR9035”, from Sartomer), ethoxylated (20) trimethylolpropanc triacrylate (available under the trade designation “SR415”, from Sartomer), polyethylene glycol (600) diacrylate (available under the trade designation “SR610”, from Sartomer), polyethylene glycol (400) diacrylate (available under the trade designation “SR344”, from Sartomer), polyethylene glycol (200) diacrylate (available under the trade designation “SR259”, from Sartomer), ethoxylated (3) bisphenol A diacrylate (available under the trade designation “SR349”, from Sartomer), ethoxylated (4) bisphenol A diacrylate (available under the trade designation “SR601”, from Sartomer), ethoxylated (10) bisphenol A diacrylate (available under the trade designation “SR602”, from Sartomer), ethoxylated (30) bisphenol A diacrylate (available under the trade designation “SR9038”, from Sartomer), propoxylated neopentyl glycol diacrylate (available under the trade designation “SR9003”, from Sartomer), polyethylene glycol dimethacrylate (available under the trade designation “SR210A”, from Sartomer), polyethylene glycol (600) dimethacrylate (available under the trade designation “SR252”, from Sartomer), polyethylene glycol (400) dimethacrylate (available under the trade designation “SR603”, from Sartomer), ethoxylated (30) bisphenol A dimethacrylate (available under the trade designation “SR9036”, from Sartomer. Combinations of polar (meth)acrylates may be used.

Other monomers that may be used and considered to be in the category of polar (meth)acrylates include N-vinylpyrrolidone; N-vinylcaprolactam; acrylamides; mono- or di-N-alkyl substituted acrylamide; t-butyl acrylamide; dimethylaminoethyl acrylamide; N-octyl acrylamide; acrylic acid, and methacrylic acid, alkyl vinyl ethers, including vinyl methyl ether;

In some embodiments, e.g. wherein the liquid, adhesive precursor is designed to solubilize a polar solvent, the composition of the liquid, adhesive precursor may include polar (meth)acrylate. In some embodiments the liquid, adhesive precursor may include at least 10 percent, at least 30 percent, at least 40 percent, at least 50 percent, at least 60 percent at least 70 percent, at least 80 percent, at least 90 percent, at least 95 percent or at least 97 percent by weight of polar (meth)acrylate. In some embodiments the liquid, adhesive precursor may include at least 10 percent, at least 20 percent, at least 30 percent and/or less than 100 percent, less than 99 percent, less than 97 percent, less than 95 percent, less than 90 percent, less than 85 percent by weight of polar (meth)acrylate. In some embodiments the liquid, adhesive precursor may include from between 50 and 100 percent, between 60 and 100 percent, between 70 and 100 percent, between 80 and 100 percent, between 90 and 100 percent, between 50 and 98 percent, between 60 and 98 percent, between 70 and 98 percent, between 80 and 98 percent, between 90 and 98 percent, between 50 and 95 percent, between 60 and 95 percent, between 70 and 95 percent, between 80 and 95 percent, between 90 and 95 percent by weight of polar meth(acrylate). In some embodiments, the polar meth(acrylate) is at least one of an ethoxylated and propoxylated (meth)acrylate.

In some embodiments, the liquid, adhesive precursor includes a crosslinker. The crosslinker often increases the cohesive strength and the tensile strength of the polymerizable liquid, adhesive precursor, i.e. the cured adhesive layer. The crosslinker can have at least two functional groups, e.g. two ethylenically unsaturated groups, which are capable of polymerizing with other components of the liquid, adhesive precursor. Suitable crosslinkers may have multiple (meth)acryloyl groups. Alternatively, the crosslinker can have at least two groups that arm capable of reacting with various functional groups (i.e., functional groups that are not ethylenically unsaturated groups) on another monomer. For example, the crosslinker can have multiple groups that can react with functional groups such as acidic groups on other monomers.

Crosslinkers with multiple (meth)acryloyl groups can be di(meth)acrylates, tri(meth)acrylates, tetra(meth)acrylates, penta(meth)acrylates, and the like. In many aspects, the crosslinkers contain at least two (meth)acryloyl groups. Exemplary crosslinkers with two acryloyl groups include, but are not limited to, 1,2-ethanediol diacrylate, 1,3-propanediol diacrylate, 1,9-nonanediol diacrylate, 1,12-dodecanediol diacrylate, 1,4-butanediol diacrylate, 1,6-hexanediol diacrylate, butylene glycol diacrylate, bisphenol A diacrylate, diethylene glycol diacrylate, triethylene glycol diacrylate, tetraethylene glycol diacrylate, tripropylene glycol diacrylate, polyethylene glycol diacrylate, polypropylene glycol diacrylate, polyethylene/polypropylene copolymer diacrylate, polybutadiene di(meth)acrylate, propoxylated glycerin tri(meth)acrylate, and neopentylglycol hydroxypivalate diacrylate modified caprolactone.

Exemplary crosslinkers with three or four (meth)acryloyl groups include, but are not limited to, trimethylolpropane triacrylate (available under the trade designation “TMPTA-N” from Cytec Industries, Inc., Smyrna, Ga. and under the trade designation “SR351” from Sartomer), pentaerythritol triacrylate (available under the trade designation “SR444” from Sartomer), tris(2-hydroxyethylisocyanurate) triacrylate (available under the trade designation “SR368” from Sartomer), a mixture of pentacrythritol triacrylate and pentaerythritol tetraacrylate (available under the trade designation “PETIA” with an approximately 1:1 ratio of tetraacrylate to triacrylate and under the trade designation “PETA-K” with an approximately 3:1 ratio of tetraacrylate to triacrylate, from Cytec Industries, Inc.), pentaerythritol tetraacrylate (available under the trade designation “SR295 from Sartomer”), di-trimethylolpropane tetraacrylate (available under the trade designation “SR355” from Sartomer), and ethoxylated pentaerythritol tetraacrylate (available under the trade designation “SR494” from Sartomer). An exemplary crosslinker with five (meth)acryloyl groups includes, but is not limited to, dipentaerythritol pentaacrylate (available under the trade designation “SR399” from Sartomer). Previously mentioned multifunctional polar (meth)acrylate may be considered crosslinkers.

In some aspects, the crosslinkers are polymeric material that contains at least two (meth)acryloyl groups. For example, the crosslinkers can be poly(alkylene oxides) with at least two acryloyl groups (polyethylene glycol diacrylates commercially available from Sartomer under the trade designation “SR210”, “SR252”, and “SR603”, for example). The crosslinkers poly(urethanes) with at least two (meth)acryloyl groups (polyurethane diacrylates such as CN9018 from Sartomer). As the higher molecular weight of the crosslinkers increases, the resulting acrylic copolymer tends to have a higher elongation before breaking. Polymeric crosslinkers tend to be used in greater weight percent amounts compared to their non-polymeric counterparts.

Other types of crosslinkers can be used rather than those having at least two (meth)acryloyl groups. The crosslinker can have multiple groups that react with functional groups such as acidic groups on other monomers. For example, monomers with multiple aziridinyl groups can be used that are reactive with carboxyl groups. For example, the crosslinkers can be a bis-amide crosslinker as described in U.S. Pat. No. 6,777,079 (Zhou et al.).

The amount of crosslinker in the liquid, adhesive precursor is not particularly limited and depends on the desired final properties of the cured adhesive layer formed therefrom. Crosslinking may improve the cohesive strength of the cured adhesive layer and facilitate removal from the surface of the substrate without leaving residue while improving the ability of the cured adhesive layer to entrap the particulate contaminant and remove it from the substrate surface. In some embodiments the liquid, adhesive precursor may include at least 5 percent, at least 10 percent, at least 30 percent, at least 40 percent, at least 50 percent, at least 60 percent at least 70 percent, at least 80 percent, at least 90 percent, at least 95 percent or at least 97 percent by weight of crosslinker. In some embodiments the liquid, adhesive precursor may include at least 5 percent at least 10 percent, at least 20 percent, at least 30 percent and/or less than 100 percent, less than 99 percent, less than 97 percent, less than 95 percent, less than 90 percent, less than 85 percent by weight of crosslinker. In some embodiments the liquid, adhesive precursor may include from between 50 and 100 percent, between 60 and 100 percent, between 70 and 100 percent, between 80 and 100 percent, between 90 and 100 percent, between 50 and 98 percent, between 60 and 98 percent, between 70 and 98 percent, between 80 and 98 percent, between 90 and 98 percent, between 50 and 95 percent, between 60 and 95 percent, between 70 and 95 percent, between 80 and 95 percent, between 90 and 95 percent by weight of crosslinker. In some embodiments, the crosslinker is a polar meth(acrylate).

Curing agents, e.g. photoinitiators, may be added to the liquid, adhesive precursor to facilitate the polymerization of the liquid, adhesive precursor. The photoinitiators are typically designed to be activated by the exposure to actinic radiation. Photoinitiators include, but are not limited to, those available under the trade designations “IRGACURE” and “DAROCUR” from BASF Corp, Florham Park, New Jersey. and include 1-hydroxy cyclohexyl phenyl ketone (trade designation “IRGACURE 184”), 2,2-dimethoxy-1,2-diphenylethan-1-one (trade designation “IRGACURE 651”), Bis(2,4,6-trimethyl benzoyl)phenylphosphineoxide (trade designation “IRGACURE 819”), 1-[4-(2-hydroxyethoxy)phenyl]-2-hydroxy-2-methyl-1-propane-1-one (trade designation “IRGACURE 2959”), 2-benzyl-2-dimethylamino-1-(4-morpholinophenyl)butanone (trade designation “IRGACURE 369”), 2-methyl-1-[4-(methylthio)phenyl]-2-morpholinopropan-1-one (trade designation “IRGACURE 907”), and 2-hydroxy-2-methyl-1-phenyl propan-1-one (trade designation “DAROCUR 1173”).

Other additives may optionally be included in the liquid, adhesive precursor and, subsequently, the cured adhesive layer. Additives include, but are not limited to pigments, tackifiers, toughening agents, reinforcing agents, fire retardants, antioxidants, antistatic agents (e.g. trimethylacryloxyethyl ammonium bis(trifluoromethyl)sulfonimide), surfactants, chelating agents, deaerators and stabilizers. The additives are added in amounts sufficient to obtain the desired end properties. In some embodiments, the amount of additive in the liquid, adhesive precursor is between 1 and 20 percent, between 1 and 10 percent or between 1 and 10 percent.

In another embodiment the present disclosure provides a laminate comprising a substrate having a first surface including a particulate contaminant disposed on the first surface; a cured adhesive layer having a first and a second major surface, wherein the first major surface of the cured adhesive layer is in contact with the first surface of the substrate and the particulate contaminant and; a film layer in contact with the second major surface of the cured adhesive layer, wherein the cured adhesive layer is the reaction product of a liquid, adhesive precursor. The cured adhesive layer may be the reaction product of any one of the liquid, adhesive precursors disclosed herein. Therefore, the cured adhesive layer may include the reaction product of the materials disclosed herein to be useful as liquid, adhesive precursors, including monomers, oligomers and/or polymers, e.g. non-polar and polar (meth)acrylates, crosslinkers, and photoinitiators. In some embodiments, the cured adhesive layer includes the reaction product of a polar meth(acrylate). In some embodiments, the cured adhesive layer includes at least 30 percent by weight of the reaction product of a polar meth(acrylate), optionally, wherein the polar meth(acrylate) is at least one of an ethoxylated and propoxylated (meth)acrylate. In some embodiments, the liquid, adhesive precursor (which forms the cured adhesive layer) has at least one of (i) a total solubility parameter of no greater than 9.20 (cal/cm³)^{0.5} and (ii) a hydrogen bonding component solubility parameter of greater than 4.50 (cal/cm³)^{0.5}.

A schematic cross-sectional diagram of a laminate 12, according to some embodiments of the present disclosure, is shown in FIG. 1B. Laminate 12 includes substrate 20 having a first surface 20a including particulate contaminant 30 disposed on first surface 20a. First surface 20a of substrate 20 may include at least one, optional, topographical feature 24. Laminate 12 also includes cured adhesive layer 44. Cured adhesive layer 44 has first major surface 44a and second major surface 44b. Cured adhesive layer 44 is the cured adhesive layer resulting from the reaction product of a liquid, adhesive precursor 40 of FIG. 1A. First major surface 44a of cured adhesive layer 44 is in contact with first surface 20a of substrate 20 and particulate contaminant 30. Particulate contaminant 30 has a longest dimension, D. Laminate 12 further includes a film layer 50 in contact with the second major surface 44b of cured adhesive layer 44. Generally, major surface 50a of film layer 50 is in contact with second major surface 44b of cured adhesive layer 44, and major surface 44b of cured adhesive layer 44 is opposite that of first surface 20a of substrate 20.

In some embodiments, laminate 12 may further include a solvent, e.g. a polar solvent, dispose on at least a portion of the first surface of the substrate. The solvent may be in the form of a continuous layer covering at least 20 percent, at least 30 percent, at least 40 percent, at least 50, at least 60 percent, at least 70 percent at least 80 percent or at least 90 percent of the area of the first surface of the substrate that is not in contact with particulate contaminant. The solvent may be the form of a plurality of isolated regions, e.g. a plurality of droplets, on the first surface of the substrate. The plurality of isolated regions of solvent may cover greater than at least 2 percent, greater than at least 5 percent, greater than at least 10 percent, greater than at least 20 percent or greater than at least 30 percent and/or less than at least 90 percent, less than at least 80 percent or less than at least 70 percent of the area of the first surface of the substrate that is not in contact with particulate contaminant. In some embodiments the solvent is a polar solvent. The polar solvent is not particularly limited. The polar solvent includes, but is not limited to water, methanol, ethanol, propanol and combinations thereof.

In some embodiments, the cured adhesive layer includes between 0.5 wt. % and 125 wt. %, between 2 wt. % and 125 wt. %, between 5 wt. % and 125 wt. %, between 10 wt. % and 125 wt. %, between 25 wt. % and 125 wt. %, between 50 wt. % and 125 wt. % or between 75 wt. % and 125 wt. % of a polar solvent, based on the weight of the cured adhesive layer excluding the polar solvent. In some embodiments the cured adhesive layer includes at least 0.5 wt. %, at least 2 wt. % at least 5 wt. %, at least 10 wt. %, at least 20 wt. % at least 30 wt. %, at least 40 wt. % at least 50 wt. %, or at least 75 wt. % and/or less than 125 wt. %, less than 100 wt. % or less than 80 wt. % of a polar solvent, based on the weight of the cured adhesive layer excluding the polar solvent. In order for the cured adhesive layer to include polar solvent at the amounts disclosed herein, the composition of the cured adhesive layer may be designed to solubilize polar solvent. In some embodiments, the cured adhesive layer is a single-phase solution. In some embodiments the cured adhesive layer includes at least 0.5 wt. %, at least 2 wt. % at least 5 wt. %, at least 10 wt. %, at least 20 wt. % at least 30 wt. % at least 40 wt. % at least 50 wt. %, or at least 75 wt. % and/or less than 125 wt. %, less than 100 wt. % or less than 80 wt. % of a polar solvent, based on the weight of the liquid, adhesive precursor excluding the polar solvent, and the cured adhesive layer is a single-phase solution.

The film layer is not particularly limited. Any of a variety of materials are suitable for the film layer, including both flexible materials and materials that are more rigid. Due to their ability to facilitate removal of the cured adhesive layer from the substrate, flexible materials may be preferred. The film layer may include polymeric film, primed polymeric film, metal foil, cloth, paper, vulcanized fiber, nonwovens and treated versions thereof and combinations thereof. In some embodiments, the film layer is non-porous. In some embodiments, e.g. wherein the liquid, adhesive precursor is designed to be polymerized, i.e. cured, by actinic radiation, or when greater flexibility is desired, the film layer may be a polymeric film or treated polymeric film. Examples of such films include, but are not limited to, polyester film (e.g. polyethylene terephthalate film, polybutylene terephthalate film, polybutylene succinate film, polylactic acid film), co-polyester film, polyimide film, polyamide film, polyurethane film, polycarbonate film, polyvinyl alcohol film, polypropylene film, polyethylene film, and the like. In some embodiments, the film layer may be biodegradable film, e.g. polybutylene succinate film, polylactic acid film. Laminates of different polymer films may be used to form the film layer. In embodiments wherein the liquid, adhesive precursor is designed to be polymerized, i.e. cured, by actinic radiation, the film layer allows for sufficient transmission of the actinic radiation to enable polymerization. In some embodiments, the film layer has a percent transmission of at least 50 percent, at least 60 percent, at least 70 percent, at least 80 percent, at least 90 percent or at least 95 percent over at least a portion of the UV/Visible light spectrum. In some embodiments, the film layer has a percent transmission, UV and/or visible radiation, of at least 50 percent, at least 60 percent, at least 70 percent, at least 80 percent, at least 90 percent or at least 95 percent over at least a portion of the visible light spectrum (about 400 to 700 nm) and/or UV light spectrum (about 100 nm to 400 nm). The percent visible light transmission may be measured by conventional techniques and equipment, such as using a HAZEGARD PLUS haze meter from BYK-Gardner Inc., Silver Springs, Maryland, to measure the percent transmission of a film layer having an average thickness from 1 to 100 micrometers, preferably from 40 to 60 micrometers. The percent UV light transmission may be measured using a portable UV radiometer available under the trade designation “POWER PUCK II”, a four-band portable UV radiometer from EIT, LLC, Leesburg, Virginia. The UV peak irradiance (Watts/cm²) and energy density (J/cm²) may be measured with and without the films and the % of radiation transmitted may be calculated, based on the difference between the values, in the UVA, UVB and UVC region of the UV spectrum. This portable UV radiometer may also be used for transmission measurements in the visible light wavelength range. The film thickness used may be from 1 to 100 micrometers, preferably from 40 to 60 micrometers for the portable UV radiometer measurements. In some embodiments, the thickness of the film layer may be between about 1 to 1,000 micrometers, between 1 to 500 micrometers, between 1 to 200 micrometers or between 1 to 100 micrometers. In some embodiments, the film layer may include an antistatic material, or the film layer may include an antistatic coating on one or both of its major surfaces. The antistatic material and/or coating may include trimethylacryloxyethyl ammonium bis(trifluoromethyl)sulfonimide and a blend of poly(3,4-ethylenedioxythiophene)/polystyrene sulfonate. In some embodiments, the film layer may be free of an antistatic material or treatment.

Generally, it is desirable to have good adhesion between the film layer and the cured adhesive layer. In many instances, the coating surface of polymeric film backing is primed to improve adhesion. The primer can involve surface alteration or application of a chemical-type primer. Examples of surface alterations include corona treatment, UV treatment, electron beam treatment, flame treatment and scuffing to increase the surface area. Examples of chemical-type primers include ethylene acrylic acid copolymer as disclosed in U.S. Pat. No. 3,188,265, colloidal dispersion as taught in U.S. Pat. No. 4,906,523, aziridine-type materials as disclosed in U.S. Pat. No. 4,749,617 and radiation grafted primers as taught in U.S. Pat. Nos. 4,563,388 and 4,933,234. In some embodiments, the peel strength between the cured adhesive layer and substrate is less than the peel strength between the cured adhesive layer and film layer.

The particulate contaminant, e.g. particulate contaminant 30, of the present disclosure is not particularly limited. The term “particulate”, with respect to the phrase “particulate contaminant” is meant to include particles, flakes, fibers, dendrites and the like. Particulate particles generally include particulates that have aspect ratios of length to width and length to thickness both of which are between 1 and 5, between 1 and 3, between 1 and 2 or between 1 and 1.5. Particulate flakes generally include particulates that have a length and a width each of which is significantly greater than the thickness of the flake. Particulate flakes include particulates that have aspect ratios of length to thickness and width to thickness each of which is greater than about 5. There is no particular upper limit on the length to thickness and width to thickness aspect ratios of a flake. Both the length to thickness and width to thickness aspect ratios of the flake may be between about 6 and about 1000, between about 6 and about 500, between about 6 and about 100, between about 6 and about 50 or between about 6 and about 25. Particulate fibers generally include particulates that have aspect ratios of the length to width and length to thickness both of which are greater about 10 and a width to thickness aspect ratio less than about 5. For a fiber having a cross sectional area that is in the shape of a circle, the width and thickness would be the same and would be equal to the diameter of the circular cross-section. There is no particular upper limit on the length to width and length to thickness aspect ratios of a fiber. Both the length to thickness and length to width aspect ratios of the fiber may be between about 10 and about 1000000, between 10 and about 100000, between 10 and about 1000, between 10 and about 500, between 10 and about 250, between 10 and about 100 or between about 10 and about 50. Particulate dendrites include particulates having a branched structure.

In some embodiments, at least a portion of the particulate contaminant has a longest dimension of no greater than 2,000 nm, no greater than 1,000 nm 500 nm, no greater than 400 nm, no greater than 300 nm, no greater than 200 nm, no greater than 100 nm or no greater than 80 nm. In some embodiments at least 50 percent, at least 60 percent, at least 70 percent, at least 80 percent, at least 90 percent, at least 95 percent or at least 99 percent of the particulate contaminant, based on particle count, has a longest dimension of no greater than 2,000 nm, no greater than 1,000 nm, no greater than 500 nm, no greater than 400 nm, no greater than 300 nm, no greater than 200 nm, no greater than 100 nm or no greater than 80 nm. In some embodiments, at least a portion of the particulate contaminant has a longest dimension of between 5 nm and 2,000 nm, between 10 nm and 2,000 nm, between 20 nm and 2,000 nm, 5 nm and 1,000 nm, between 10 nm and 1,000 nm, between 20 nm and 1,000 nm, 5 nm and 500 nm, between 10 nm and 500 nm, between 20 nm and 500 nm, between 5 nm and 300 nm, between 10 nm and 30 nm, between 20 nm and 300 nm, between 5 nm and 100 nm, between 10 nm and 100 nm or between 20 nm and 100 nm. In some embodiments, at least 50 percent, at least 60 percent, at least 70 percent, at least 80 percent, at least 90 percent, at least 95 percent or at least 99 percent of the particulate contaminant, based on particle count, has a longest dimension of between 5 nm and 2,000 nm, between 10 nm and 2,000 nm, between 20 nm and 2,000 nm, 5 nm and 1,000 nm, between 10 nm and 1,000 nm, between 20 nm and 1,000 nm, between 5 nm and 500 nm, between 10 nm and 500 nm, between 20 nm and 500 nm, between 5 nm and 300 nm, between 10 nm and 30 nm, between 20 nm and 300 nm, between 5 nm and 100 nm, between 10 nm and 100 nm or between 20 nm and 100 nm. In some embodiments, the particulate contaminant may be spheroidal in shape and, optionally, may have a longest dimension of between 5 nm and 2,000 nm, between 10 nm and 2,000 nm, between 20 nm and 2,000 nm, 5 nm and 1,000 nm, between 10 nm and 1,000 nm, between 20 nm and 1,000 nm, between 5 nm and 500 nm, between 10 nm and 500 nm, between 20 nm and 500 nm, between 5 nm and 300 nm, between 10 nm and 30 nm, between 20 nm and 300 nm, between 5 nm and 100 nm, between 10 nm and 100 nm or between 20 nm and 100 nm. In some embodiments, a spheroidal shape is defined as a spheroid having an aspect ratio (the ratio of the longest dimension to shortest dimension) less than 1.5, less than 1.25 or less than 1.1.

The substrate, e.g. substrate 20, of the laminates, e.g. laminates 10 and 12, of the present disclosure is not particularly limited and may include, but is not limited to, semiconductor wafer, a plate, a roll, e.g. a roll used for precision coating, wafer processing equipment, e.g. equipment chambers, precision lenses, optical devices and films, e.g. polymeric films and metal films. The substrate, e.g. substrate, 20 may include at least one, optional, topographical feature 24. The substrate and at least one topographical feature may be an integral body, they may be separate components (which may be fabricated from different or similar materials) and joined together, or combinations thereof. The topographical features of the present disclosure are not particularly limited and may include, for example, conventional topographical features found on semiconductor wafer surface during their processing and, for example, a knurl pattern machined in a coating roll.

The present disclosure further provides methods of cleaning a substrate surface, i.e. methods that allow for the removal of contaminants, e.g. particulate contaminants, from a substrate surface. In the methods of cleaning a substrate surface of the present disclosure, the substrate may be any of the substrates disclosed herein, the particulate contaminant may be any of the particular contaminants disclosed herein, the liquid, adhesive precursor may be any of the liquid, adhesive precursors disclosed herein, the film layer may be any of the film layers disclosed herein and the curing mechanism of the liquid, adhesive precursor may be any of the curing mechanisms disclosed herein. In some embodiments, the substrate surface may also include a polar solvent.

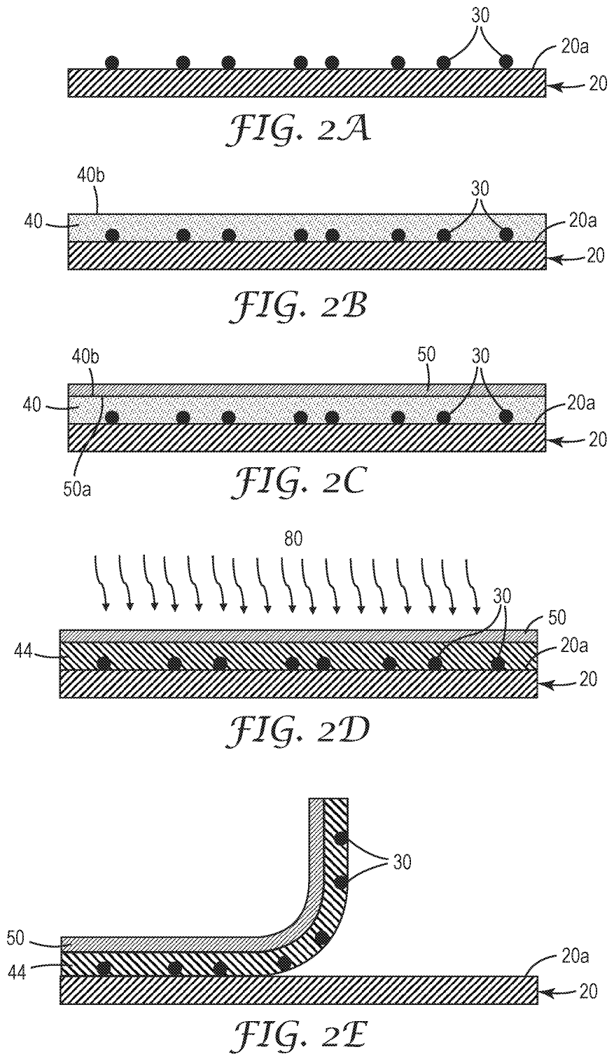

FIGS. 2A-2E, i.e. steps (A) through (E), depict a method of cleaning a substrate surface. Step A (FIG. 2A) includes providing a substrate 20 having a first surface 20a including a particulate contaminant 30. First surface 20a may also, optionally, include a polar solvent disposed on the first surface 20a (not shown). First surface 20a may also, optionally, include at least one topographical feature (not shown). In some embodiments, at least a portion of the particulate contaminant has a longest dimension of no greater than 500 nm and, optionally, at least 50% of the particulate contaminant, based on particulate count, has a longest dimension of no greater than 500 nm. Step B (FIG. 2B) includes coating at least a portion of the first surface 20a, including the particulate contaminant and the polar solvent, if present, with a liquid, adhesive precursor 40. Liquid, adhesive precursor 40 includes major surface 40b, and liquid, adhesive precursor major surface 40b is opposite that of first surface 20a of substrate 20. In some embodiments, liquid, adhesive precursor has at least one of (i) a total solubility parameter of no greater than 9.20 (cal/cm³)^{0.5} and (ii) a hydrogen bonding component solubility parameter of greater than 4.50 (cal/cm³)^{0.5}. The liquid, adhesive precursor may include a polar (meth)acrylate. In some embodiments, the liquid, adhesive precursor may include at least 30 wt. % of the polar (meth)acrylate. In yet another embodiment, the polar (meth)acrylate is at least one of an ethoxylated and propoxylated (meth)acrylate. In some embodiments, when a polar solvent is disposed on the substrate first surface, at least a portion of the polar solvent is absorbed by the liquid, adhesive precursor. In some embodiments, the liquid, adhesive may absorb between 0.5 wt. % and 125 wt. % of a polar solvent, based on the weight of the liquid, adhesive precursor. The polar solvent includes water, methanol, ethanol, propanol and combinations thereof. In some embodiments, the liquid, adhesive precursor is a single-phase solution, after absorbing at least a portion of the polar solvent.

Step C (FIG. 2C) includes disposing a film layer 50, having major surface 50a, on the liquid, adhesive precursor 40, having major surface 40b. This produces a laminate similar to laminate 10 of the present disclosure. Generally, major surface 50a of film layer 50 is in contact with liquid, adhesive precursor major surface 40b, and liquid, adhesive precursor major surface 40b is opposite that of first surface 20a of substrate 20. In some embodiments, the film layer has a percent transmission of at least 50% over at least a portion of the UV/Visible light spectrum. The film layer may be non-porous. Step D (FIG. 2D) includes providing actinic radiation 80 through film layer 50, thereby curing the liquid, adhesive precursor 40 and forming a cured adhesive layer 44, which entraps the particulate contaminant. This produces a laminate similar to laminate 12 of the present disclosure. Optionally, if a different curing mechanism for the liquid, adhesive precursor is employed, for example, thermal curing replacing curing by actinic radiation, the liquid, adhesive precursor may be cured by applying heat, via conventional means, thereby curing the liquid, adhesive precursor 40 and forming a cured adhesive layer 44, which entraps the particulate contaminant. Step E (FIG. 2E) includes removing film layer 50, cured adhesive layer 44 and at least a portion of particulate contaminant 30 from the first surface. Generally, film layer 50 and cured adhesive layer 44 are removed simultaneously, as there is adequate adhesion between the cured adhesive layer and the film layer. In some embodiments, at least 40 percent, at least 50 percent, at least 60 percent, at least 70 percent, at least 80 percent, at least 90 percent, at least 95 percent, at least 97 percent, at least 99 percent or even 100 percent of the particulate contaminant, based on at least one of particle count and surface area of the substrate cleaned, is removed from the first surface of the substrate.

In an alternative embodiment (not shown), Step B in the previous method of cleaning a substrate surface may be replaced by providing a film layer 50 with major surface 50a and coating at least a portion of major surface 50a with a liquid, adhesive precursor 40. Step C in the previous method of cleaning a substrate surface is then replaced by applying the exposed surface of liquid, adhesive precursor 40 on film layer 50 to at least a portion of the first surface 20a of substrate 20, including the particulate contaminant and the polar solvent, if present. Steps A, D and E would be substantially the same as described in the previous method of cleaning a substrate surface.

In some embodiments, the substrates, e.g. wafer substrates after CMP processing, may include a pre-cleaning step, prior to conducting the methods of cleaning a substrate surface of the present disclosure. Pre-cleaning may include rinsing, e.g. dip tank rinse or spin rinse, with an appropriate cleaning agent, for example solvent, HF, NH₃, tetramethyl ammonium hydroxide and combinations thereof and/or substrates, e.g. wafer substrates after CMP processing, may include a post-cleaning step, after conducting the methods of cleaning a substrate surface of the present disclosure. Post-cleaning may include rinsing, e.g. dip tank rinse or spin rinse, with an appropriate cleaning agent, for example solvent, HF, H₂O₂, SC1 (1:1:5 Ammonia:Hydrogen Peroxide:DI water mixture based on volume) and combinations thereof.

### EXAMPLES

Unless otherwise noted or readily apparent from the context, all parts, percentages, ratios, etc. in the Examples and the rest of the specification are by weight.

Materials Used in the Examples

| Abbreviation | Description and Source |
|---|---|
| SR351H | Trimethylolpropane triacrylate, a UV curable resin available under the |
| | trade designation “SR351H”, from Sartomer, Exton, Pennsylvania. |
| SR454 | Ethoxylated (3) trimethylolpropane triacrylate, a UV curable resin |
| | available under the trade designation “SR454”, from Sartomer. |
| SR499 | Ethoxylated (6) trimethylolpropane triacrylate, a UV curable resin |
| | available under the trade designation “SR499”, from Sartomer. |
| SR502 | Ethoxylated (9) trimethylolpropane triacrylate, a UV curable resin |
| | available under the trade designation “SR502”, from Sartomer. |
| SR9035 | Ethoxylated (15) trimethylolpropane triacrylate, a UV curable resin |
| | available under the trade designation “SR9035”, from Sartomer. |
| SR415 | Ethoxylated (20) trimethylolpropane triacrylate, a UV curable resin |
| | available under the trade designation “SR415”, from Sartomer. |
| SR349 | Ethoxylated (3) bisphenol A diacrylate, a UV curable resin available |
| | under the trade designation “SR349”, from Sartomer. |
| SR601 | Ethoxylated (4) bisphenol A diacrylate, a UV curable resin available |
| | under the trade designation “SR454”, from Sartomer. |
| SR602 | Ethoxylated (10) bisphenol A diacrylate, a UV curable resin available |
| | under the trade designation “SR602”, from Sartomer as SR602. |
| SR9036 | Ethoxylated (30) bisphenol A dimethacrylate, a UV curable resin |
| | available under the trade designation “SR9036”, from Sartomer |
| SR9038 | Ethoxylated (30) bisphenol A diacrylate, a UV curable resin available |
| | under the trade designation “SR9038”, from Sartomer. |
| SR272 | Triethylene glycol (200) diacrylate, a UV curable resin available under |
| | the trade designation “SR272”, from Sartomer. |
| SR268 | Tetraethylene glycol diacrylate, a UV curable resin available under the |
| | trade designation “SR272”, from Sartomer. |
| SR259 | Polyethylene glycol (200) diacrylate, a UV curable resin available under |
| | the trade designation “SR272”, from Sartomer. |
| SR344 | Polyethylene glycol (400) diacrylate, a UV curable resin available under |
| | the trade designation “SR272”, from Sartomer. |
| IRG819 | Bis (2,4,6-trimethylbenzoyl)-phenylphosphine oxide, a photoinitiator |
| | available under the trade designation “IRGACURE 819”, from BASF |
| | Corporation, Florham Park, New Jersey. |
| IRG2959 | 1-[4-(2-Hydroxyethoxy)-phenyl]-2-hydroxy-2-methyl-1-propane-1-one, a |
| | photoinitiator available under the trade designation “IRGACURE 2959”, |
| | from BASF Corporation. |
| TPO-L | Ethyl(2,4,6-Trimethylbenzoyl)-phenyl phosphinate photoinitiator |
| | available under the trade designation “OMNIRAD TPO-L” from IGM |
| | Resins USA Inc., Charlotte, North Carolina. |
| PET1 | 2 mil (51 micron) polyethylene terephthalate film, available under the |
| | trade designation “SCOTCHPAK POLYESTER FILM”, from 3M |
| | Company, St. Paul, Minnesota. |
| D9228 | Colloidal silica-based slurry, 50 nm particle size, available under the |
| | trade designation “IDIEL D9228” from Cabot Micro Electronics |
| | Corporation, Aurora, Illinois. |
| SI WAFER1 | 8 inch (200 mm) diameter silicon wafer, 15,000 Å thick PETEOS |
| | (Plasma Enhanced Tetra Ethyl Orthosilicate) film deposited on Prime |
| | Silicon (P doped), from Advantiv Technologies, Inc., Fremont, |
| | California. |
| SI WAFER2 | 2 inch (50.8 mm) diameter silicon wafer, 10,000 Å thick thermal oxide |
| | film grown on Silicon, from Advantiv Technologies, Inc., Fremont, |
| | California. |

### Test Methods

### Solubility Parameter Calculations

The total solubility parameter (Total SP) is determined based on the group contribution calculations as defined by P. A. Small in the J. Appl. Chem., 3, 71(1953).

The Hydrogen Bonding Component Solubility Parameter (H-Bonding SP) is determined based on the hydrogen bonding component of the group contribution calculations as defined by Hansen in the “Hansen Solubility Parameters: A User's Handbook”, CRC Press, Inc., Boca Raton FL, 1999. The hydrogen bonding component solubility parameter may be calculated using a software program available under the trade designation “Molecular Modeling Pro Plus”, from Norgwyn Montgomery Software, Inc., North Wales, Pennsylvania.

If a mixture of compounds is used to form the liquid, adhesive precursor, the solubility parameter of each compound is calculated individually and then the solubility parameter, e.g. (Total SP) and/or H-Bonding SP, of the liquid, adhesive precursor (mixture) is defined as the sum of the products of the solubility parameter of each compound times its mole fraction in the mixture.

### Preparatory Examples (PEs)—Water Compatibility

Preparatory examples (PEs) of liquid, adhesive precursors were prepared according to Table 1. IRG819, 2 wt. %, was dissolved into the designated UV curable resin.

TABLE 1
Liquid Adhesive Precursors

| Preparatory | UV Curable | UV Curable Resin | IRG819 |
|---|---|---|---|
| Example | Resin | (wt. %) | (wt. %) |
| PE1 | SR351H | 98 | 2 |
| PE2 | SR454 | 98 | 2 |
| PE3 | SR499 | 98 | 2 |
| PE4 | SR502 | 98 | 2 |
| PE5 | SR9035 | 98 | 2 |
| PE6 | SR415 | 98 | 2 |
| PE7 | SR349 | 98 | 2 |
| PE8 | SR601 | 98 | 2 |
| PE9 | SR602 | 98 | 2 |
| PE10 | SR9038 | 98 | 2 |
| PE11 | SR772 | 98 | 2 |
| PE12 | SR268 | 98 | 2 |
| PE13 | SR259 | 98 | 2 |
| PE14 | SR344 | 98 | 2 |

Twelve aliquots of each of the preparatory examples above were mixed with deionized water according to the formulations shown in Tables 2-1 through 2-14. Values of the percent water in the liquid adhesive precursor are calculated based on the weight of the liquid adhesive precursor as the basis, not the weight of liquid adhesive precursor plus the weight of water. Upon the addition of water, the solutions were blended on a vortex mixer for 5 to 10 seconds each. After 10 min., the solutions were observed for their compatibility with water. Results varied from a homogeneous single-phase appearance to small emulsified water droplets to large separated droplets to gross phase separation with a distinct water layer separating to the top of the solution, see Tables 3-1 through 3-14. The total solubility parameter (Total SP) and the hydrogen bonding component solubility parameter (H-Bonding SP) are also shown in Tables 3-1 through 3-14. These values are calculated based on the chemical structure of the liquid, adhesive precursor. The polar solvent, water, is not included in the calculation.

TABLE 2-1
Liquid Adhesive Precursor PE1 with Deionized Water (values in grams except indicated %)

| | PE1a | PE1b | PE1c | PE1d | PE1e | PE1f | PE1g | PE1h | PE1i | PE1j | PE1k | PE1l |
|---|---|---|---|---|---|---|---|---|---|---|---|---|
| PE1 | 10.00 | 9.95 | 9.875 | 9.75 | 9.50 | 9.25 | 9.00 | 8.75 | 7.50 | 6.00 | 4.50 | 3.0 |
| Water | 0.00 | 0.05 | 0.125 | 0.25 | 0.50 | 0.75 | 1.00 | 1.25 | 2.50 | 4.00 | 5.50 | 7.0 |
| Water | 0.00 | 0.503 | 1.266 | 2.564 | 5.102 | 8.108 | 11.11 | 14.28 | 33.33 | 66.67 | 122.2 | 233.3 |
| (%) | | | | | | | | | | | | |

TABLE 2-2
Liquid Adhesive Precursor PE2 with Deionized Water (values in grams except indicated %)

| | PE2a | PE2b | PE2c | PE2d | PE2e | PE2f | PE2g | PE2h | PE2i | PE2j | PE2k | PE2l |
|---|---|---|---|---|---|---|---|---|---|---|---|---|
| PE2 | 10.00 | 9.95 | 9.875 | 9.75 | 9.50 | 9.25 | 9.00 | 8.75 | 7.50 | 6.00 | 4.50 | 3.0 |
| Water | 0.00 | 0.05 | 0.125 | 0.25 | 0.50 | 0.75 | 1.00 | 1.25 | 2.50 | 4.00 | 5.50 | 7.0 |
| Water | 0.00 | 0.503 | 1.266 | 2.564 | 5.102 | 8.108 | 11.11 | 14.28 | 33.33 | 66.67 | 122.2 | 233.3 |
| (%) | | | | | | | | | | | | |

TABLE 2-3
Liquid Adhesive Precursor PE3 with Deionized Water (values in grams except indicated %)

| | PE3a | PE3b | PE3c | PE3d | PE3e | PE3f | PE3g | PE3h | PE3i | PE3j | PE3k | PE3l |
|---|---|---|---|---|---|---|---|---|---|---|---|---|
| PE3 | 10.00 | 9.95 | 9.875 | 9.75 | 9.50 | 9.25 | 9.00 | 8.75 | 7.50 | 6.00 | 4.50 | 3.0 |
| Water | 0.00 | 0.05 | 0.125 | 0.25 | 0.50 | 0.75 | 1.00 | 1.25 | 2.50 | 4.00 | 5.50 | 7.0 |
| Water | 0.00 | 0.503 | 1.266 | 2.564 | 5.102 | 8.108 | 11.11 | 14.28 | 33.33 | 66.67 | 122.2 | 233.3 |
| (%) | | | | | | | | | | | | |

TABLE 2-4
Liquid Adhesive Precursor PE4 with Deionized Water (values in grams except indicated %)

| | PE4a | PE4b | PE4c | PE4d | PE4e | PE4f | PE4g | PE4h | PE4i | PE4j | PE4k | PE4l |
|---|---|---|---|---|---|---|---|---|---|---|---|---|
| PE4 | 10.00 | 9.95 | 9.875 | 9.75 | 9.50 | 9.25 | 9.00 | 8.75 | 7.50 | 6.00 | 4.50 | 3.0 |
| Water | 0.00 | 0.05 | 0.125 | 0.25 | 0.50 | 0.75 | 1.00 | 1.25 | 2.50 | 4.00 | 5.50 | 7.0 |
| Water | 0.00 | 0.503 | 1.266 | 2.564 | 5.102 | 8.108 | 11.11 | 14.28 | 33.33 | 66.67 | 122.2 | 233.3 |
| (%) | | | | | | | | | | | | |

TABLE 2-5
Liquid Adhesive Precursor PE5 with Deionized Water (values in grams except indicated %)

| | PE5a | PE5b | PE5c | PE5d | PE5e | PE5f | PE5g | PE5h | PE5i | PE5j | PE5k | PE5l |
|---|---|---|---|---|---|---|---|---|---|---|---|---|
| PE5 | 10.00 | 9.95 | 9.875 | 9.75 | 9.50 | 9.25 | 9.00 | 8.75 | 7.50 | 6.00 | 4.50 | 3.0 |
| Water | 0.00 | 0.05 | 0.125 | 0.25 | 0.50 | 0.75 | 1.00 | 1.25 | 2.50 | 4.00 | 5.50 | 7.0 |
| Water | 0.00 | 0.503 | 1.266 | 2.564 | 5.102 | 8.108 | 11.11 | 14.28 | 33.33 | 66.67 | 122.2 | 233.3 |
| (%) | | | | | | | | | | | | |

TABLE 2-6
Liquid Adhesive Precursor PE6 with Deionized Water (values in grams except indicated %)

| | PE6a | PE6b | PE6c | PE6d | PE6e | PE6f | PE6g | PE6h | PE6i | PE6j | PE6k | PE6l |
|---|---|---|---|---|---|---|---|---|---|---|---|---|
| PE6 | 10.00 | 9.95 | 9.875 | 9.75 | 9.50 | 9.25 | 9.00 | 8.75 | 7.50 | 6.00 | 4.50 | 3.0 |
| Water | 0.00 | 0.05 | 0.125 | 0.25 | 0.50 | 0.75 | 1.00 | 1.25 | 2.50 | 4.00 | 5.50 | 7.0 |
| Water | 0.00 | 0.503 | 1.266 | 2.564 | 5.102 | 8.108 | 11.11 | 14.28 | 33.33 | 66.67 | 122.2 | 233.3 |
| (%) | | | | | | | | | | | | |

TABLE 2-7
Liquid Adhesive Precursor PE7 with Deionized Water (values in grams except indicated %)

| | PE7a | PE7b | PE7c | PE7d | PE7e | PE7f | PE7g | PE7h | PE7i | PE7j | PE7k | PE7l |
|---|---|---|---|---|---|---|---|---|---|---|---|---|
| PE7 | 10.00 | 9.95 | 9.875 | 9.75 | 9.50 | 9.25 | 9.00 | 8.75 | 7.50 | 6.00 | 4.50 | 3.0 |
| Water | 0.00 | 0.05 | 0.125 | 0.25 | 0.50 | 0.75 | 1.00 | 1.25 | 2.50 | 4.00 | 5.50 | 7.0 |
| Water | 0.00 | 0.503 | 1.266 | 2.564 | 5.102 | 8.108 | 11.11 | 14.28 | 33.33 | 66.67 | 122.2 | 233.3 |
| (%) | | | | | | | | | | | | |

TABLE 2-8
Liquid Adhesive Precursor PE8 with Deionized Water (values in grams except indicated %)

| | PE8a | PE8b | PE8c | PE8d | PE8e | PE8f | PE8g | PE8h | PE8i | PE8j | PE8k | PE8l |
|---|---|---|---|---|---|---|---|---|---|---|---|---|
| PE8 | 10.00 | 9.95 | 9.875 | 9.75 | 9.50 | 9.25 | 9.00 | 8.75 | 7.50 | 6.00 | 4.50 | 3.0 |
| Water | 0.00 | 0.05 | 0.125 | 0.25 | 0.50 | 0.75 | 1.00 | 1.25 | 2.50 | 4.00 | 5.50 | 7.0 |
| Water | 0.00 | 0.503 | 1.266 | 2.564 | 5.102 | 8.108 | 11.11 | 14.28 | 33.33 | 66.67 | 122.2 | 233.3 |
| (%) | | | | | | | | | | | | |

TABLE 2-9
Liquid Adhesive Precursor PE9 with Deionized Water
(values in grams except indicated percent)

| | PE9a | PE9b | PE9c | PE9d | PE9e | PE9f | PE9g | PE9h | PE9i | PE9j | PE9k | PE9l |
|---|---|---|---|---|---|---|---|---|---|---|---|---|
| PE9 | 10.00 | 9.95 | 9.875 | 9.75 | 9.50 | 9.25 | 9.00 | 8.75 | 7.50 | 6.00 | 4.50 | 3.0 |
| Water | 0.00 | 0.05 | 0.125 | 0.25 | 0.50 | 0.75 | 1.00 | 1.25 | 2.50 | 4.00 | 5.50 | 7.0 |
| Water | 0.00 | 0.503 | 1.266 | 2.564 | 5.102 | 8.108 | 11.11 | 14.28 | 33.33 | 66.67 | 122.2 | 233.3 |
| (%) | | | | | | | | | | | | |

TABLE 2-10
Liquid Adhesive Precursor PE10 with Deionized Water (values in grams except indicated %)

| | PE10a | PE10b | PE10c | PE10d | PE10e | PE10f | PE10g | PE10h | PE10i | PE10j | PE10k | PE10l |
|---|---|---|---|---|---|---|---|---|---|---|---|---|
| PE10 | 10.00 | 9.95 | 9.875 | 9.75 | 9.50 | 9.25 | 9.00 | 8.75 | 7.50 | 6.00 | 4.50 | 3.0 |
| Water | 0.00 | 0.05 | 0.125 | 0.25 | 0.50 | 0.75 | 1.00 | 1.25 | 2.50 | 4.00 | 5.50 | 7.0 |
| Water | 0.00 | 0.503 | 1.266 | 2.564 | 5.102 | 8.108 | 11.11 | 14.28 | 33.33 | 66.67 | 122.2 | 233.3 |
| (%) | | | | | | | | | | | | |

TABLE 2-11
Liquid Adhesive Precursor PE11 with Deionized Water (values in grams except indicated %)

| | PE11a | PE11b | PE11c | PE11d | PE11e | PE11f | PE11g | PE11h | PE11i | PE11j | PE11k | PE11l |
|---|---|---|---|---|---|---|---|---|---|---|---|---|
| PE11 | 10.00 | 9.95 | 9.875 | 9.75 | 9.50 | 9.25 | 9.00 | 8.75 | 7.50 | 6.00 | 4.50 | 3.0 |
| Water | 0.00 | 0.05 | 0.125 | 0.25 | 0.50 | 0.75 | 1.00 | 1.25 | 2.50 | 4.00 | 5.50 | 7.0 |
| Water | 0.00 | 0.503 | 1.266 | 2.564 | 5.102 | 8.108 | 11.11 | 14.28 | 33.33 | 66.67 | 122.2 | 233.3 |
| (%) | | | | | | | | | | | | |

TABLE 2-12
Liquid Adhesive Precursor PE12 with Deionized Water (values in grams except indicated %)

| | PE12a | PE12b | PE12c | PE12d | PE12e | PE12f | PE12g | PE12h | PE12i | PE12j | PE12k | PE12l |
|---|---|---|---|---|---|---|---|---|---|---|---|---|
| PE12 | 10.00 | 9.95 | 9.875 | 9.75 | 9.50 | 9.25 | 9.00 | 8.75 | 7.50 | 6.00 | 4.50 | 3.0 |
| Water | 0.00 | 0.05 | 0.125 | 0.25 | 0.50 | 0.75 | 1.00 | 1.25 | 2.50 | 4.00 | 5.50 | 7.0 |
| Water | 0.00 | 0.503 | 1.266 | 2.564 | 5.102 | 8.108 | 11.11 | 14.28 | 33.33 | 66.67 | 122.2 | 233.3 |
| (%) | | | | | | | | | | | | |

TABLE 2-13
Liquid Adhesive Precursor PE13 with Deionized Water (values in grams except indicated %)

| | PE13a | PE13b | PE13c | PE13d | PE13e | PE13f | PE13g | PE13h | PE13i | PE13j | PE13k | PE13l |
|---|---|---|---|---|---|---|---|---|---|---|---|---|
| PE13 | 10.00 | 9.95 | 9.875 | 9.75 | 9.50 | 9.25 | 9.00 | 8.75 | 7.50 | 6.00 | 4.50 | 3.0 |
| Water | 0.00 | 0.05 | 0.125 | 0.25 | 0.50 | 0.75 | 1.00 | 1.25 | 2.50 | 4.00 | 5.50 | 7.0 |
| Water | 0.00 | 0.503 | 1.266 | 2.564 | 5.102 | 8.108 | 11.11 | 14.28 | 33.33 | 66.67 | 122.2 | 233.3 |
| (%) | | | | | | | | | | | | |

TABLE 2-14
Liquid Adhesive Precursor PE14 with Deionized Water (values in grams except indicated %)

| | PE14a | PE14b | PE14c | PE14d | PE14e | PE14f | PE14g | PE14h | PE14i | PE14j | PE14k | PE14l |
|---|---|---|---|---|---|---|---|---|---|---|---|---|
| PE14 | 10.00 | 9.95 | 9.875 | 9.75 | 9.50 | 9.25 | 9.00 | 8.75 | 7.50 | 6.00 | 4.50 | 3.0 |
| Water | 0.00 | 0.05 | 0.125 | 0.25 | 0.50 | 0.75 | 1.00 | 1.25 | 2.50 | 4.00 | 5.50 | 7.0 |
| Water | 0.00 | 0.503 | 1.266 | 2.564 | 5.102 | 8.108 | 11.11 | 14.28 | 33.33 | 66.67 | 122.2 | 233.3 |
| (%) | | | | | | | | | | | | |

TABLE 3-1
Compatibility of Liquid Adhesive Precursors
(PE1) with Deionized Water

| | Water | Total SP | H-Bonding SP | Observed Compatibility |
|---|---|---|---|---|
| | (%) | (cal/cm³)^{0.5} | (cal/cm³)^{0.5} | with Water |
| PE1a | 0.00 | 9.31 | 2.61 | — |
| PE1b | 0.503 | 9.31 | 2.61 | Emulsified water droplets |
| PE1c | 1.266 | 9.31 | 2.61 | Emulsified water droplets |
| PE1d | 2.564 | 9.31 | 2.61 | Emulsified water droplets |
| PE1e | 5.102 | 9.31 | 2.61 | Emulsified water droplets |
| PE1f | 8.108 | 9.31 | 2.61 | Emulsified water droplets |
| PE1g | 11.11 | 9.31 | 2.61 | Emulsified water droplets |
| PE1h | 14.28 | 9.31 | 2.61 | Emulsified water droplets |
| PE1i | 33.33 | 9.31 | 2.61 | Water separates to top |
| PE1j | 66.67 | 9.31 | 2.61 | Water separates to top |
| PE1k | 122.2 | 9.31 | 2.61 | Water separates to top |
| PE1l | 233.3 | 9.31 | 2.61 | Water separates to top |

TABLE 3-2
Compatibility of Liquid Adhesive Precursors
(PE2) with Deionized Water

| | Water | Total SP | H-Bonding SP | Observed Compatibility |
|---|---|---|---|---|
| | (%) | (cal/cm³)^{0.5} | (cal/cm³)^{0.5} | with Water |
| PE2a | 0.00 | 9.00 | 4.95 | |
| PE2b | 0.503 | 9.00 | 4.95 | Single phase |
| PE2c | 1.266 | 9.00 | 4.95 | Single phase |
| PE2d | 2.564 | 9.00 | 4.95 | Emulsified water droplets |
| PE2e | 5.102 | 9.00 | 4.95 | Emulsified water droplets |
| PE2f | 8.108 | 9.00 | 4.95 | Emulsified water droplets |
| PE2g | 11.11 | 9.00 | 4.95 | Emulsified water droplets |
| PE2h | 14.28 | 9.00 | 4.95 | Emulsified water drops |
| | | | | Water separates to top |
| PE2i | 33.33 | 9.00 | 4.95 | Water separates to top |
| PE2j | 66.67 | 9.00 | 4.95 | Water separates to top |
| PE2k | 122.2 | 9.00 | 4.95 | Water separates to top |
| PE2l | 233.3 | 9.00 | 4.95 | Water separates to top |

TABLE 3-3
Compatibility of Liquid Adhesive Precursors
(PE3) with Deionized Water

| | Water | Total SP | H-Bonding SP | Observed Compatibility |
|---|---|---|---|---|
| | (%) | (cal/cm³)^{0.5} | (cal/cm³)^{0.5} | with Water |
| PE3a | 0.00 | 8.90 | 5.31 | — |
| PE3b | 0.503 | 8.90 | 5.31 | Single phase |
| PE3c | 1.266 | 8.90 | 5.31 | Single phase |
| PE3d | 2.564 | 8.90 | 5.31 | Single phase |
| PE3e | 5.102 | 8.90 | 5.31 | Emulsified water droplets |
| PE3f | 8.108 | 8.90 | 5.31 | Emulsified water droplets |
| PE3g | 11.11 | 8.90 | 5.31 | Emulsified water droplets |
| PE3h | 14.28 | 8.90 | 5.31 | Emulsified water droplets |
| PE3i | 33.33 | 8.90 | 5.31 | Water separates to top |
| PE3j | 66.67 | 8.90 | 5.31 | Water separates to top |
| PE3k | 122.2 | 8.90 | 5.31 | Water separates to top |
| PE3l | 233.3 | 8.90 | 5.31 | Water separates to top |

TABLE 3-4
Compatibility of Liquid Adhesive Precursors
(PE4) with Deionized Water

| | Water | Total SP | H-Bonding SP | Observed Compatibility |
|---|---|---|---|---|
| | (%) | (cal/cm³)^{0.5} | (cal/cm³)^{0.5} | with Water |
| PE4a | 0.00 | 8.83 | 5.45 | — |
| PE4b | 0.503 | 8.83 | 5.45 | Single phase |
| PE4c | 1.266 | 8.83 | 5.45 | Single phase |
| PE4d | 2.564 | 8.83 | 5.45 | Single phase |
| PE4e | 5.102 | 8.83 | 5.45 | Single phase |
| PE4f | 8.108 | 8.83 | 5.45 | Single phase |
| PE4g | 11.11 | 8.83 | 5.45 | Emulsified water droplets |
| | | | | with gel or precipitate |
| PE4h | 14.28 | 8.83 | 5.45 | Emulsified water droplets |
| | | | | with gel or precipitate |
| PE4i | 33.33 | 8.83 | 5.45 | Emulsified water droplets |
| | | | | with gel or precipitate |
| PE4j | 66.67 | 8.83 | 5.45 | Water separates to top |
| PE4k | 122.2 | 8.83 | 5.45 | Water separates to top |
| PE4l | 233.3 | 8.83 | 5.45 | Water separates to top |

TABLE 3-5
Compatibility of Liquid Adhesive Precursors
(PE5) with Deionized Water

| | Water | Total SP | H-Bonding SP | Observed Compatibility |
|---|---|---|---|---|
| | (%) | (cal/cm³)^{0.5} | (cal/cm³)^{0.5} | with Water |
| PE5a | 0.00 | 8.76 | 5.77 | — |
| PE5b | 0.503 | 8.76 | 5.77 | Single phase |
| PE5c | 1.266 | 8.76 | 5.77 | Single phase |
| PE5d | 2.564 | 8.76 | 5.77 | Single phase |
| PE5e | 5.102 | 8.76 | 5.77 | Single phase |
| PE5f | 8.108 | 8.76 | 5.77 | Single phase |
| PE5g | 11.11 | 8.76 | 5.77 | Single phase |
| PE5h | 14.28 | 8.76 | 5.77 | Single phase |
| PE5i | 33.33 | 8.76 | 5.77 | Single phase |
| PE5j | 66.67 | 8.76 | 5.77 | Single phase |
| PE5k | 122.2 | 8.76 | 5.77 | Water separates to top |
| PE5l | 233.3 | 8.76 | 5.77 | Water separates to top |

TABLE 3-6
Compatibility of Liquid Adhesive Precursors
(PE6) with Deionized Water

| | Water | Total SP | H-Bonding SP | Observed Compatibility |
|---|---|---|---|---|
| | (%) | (cal/cm³)^{0.5} | (cal/cm³)^{0.5} | with Water |
| PE6a | 0.00 | 8.73 | 5.89 | — |
| PE6b | 0.503 | 8.73 | 5.89 | Single phase |
| PE6c | 1.266 | 8.73 | 5.89 | Single phase |
| PE6d | 2.564 | 8.73 | 5.89 | Single phase |
| PE6e | 5.102 | 8.73 | 5.89 | Single phase |
| PE6f | 8.108 | 8.73 | 5.89 | Single phase |
| PE6g | 11.11 | 8.73 | 5.89 | Single phase |
| PE6h | 14.28 | 8.73 | 5.89 | Single phase |
| PE6i | 33.33 | 8.73 | 5.89 | Single phase |
| PE6j | 66.67 | 8.73 | 5.89 | Single phase |
| PE6k | 122.2 | 8.73 | 5.89 | Emulsified water droplets |
| PE6l | 233.3 | 8.73 | 5.89 | Emulsified water droplets |

TABLE 3-7
Compatibility of Liquid Adhesive Precursors
(PE7) with Deionized Water

| | Water | Total SP | H-Bonding SP | Observed Compatibility |
|---|---|---|---|---|
| | (%) | (cal/cm³)^{0.5} | (cal/cm³)^{0.5} | with Water |
| PE7a | 0.00 | 9.50 | 4.65 | — |
| PE7b | 0.503 | 9.50 | 4.65 | Single phase |
| PE7c | 1.266 | 9.50 | 4.65 | Single phase |
| PE7d | 2.564 | 9.50 | 4.65 | Emulsified water droplets |
| PE7e | 5.102 | 9.50 | 4.65 | Emulsified water droplets |
| PE7f | 8.108 | 9.50 | 4.65 | Emulsified water droplets |
| PE7g | 11.11 | 9.50 | 4.65 | Emulsified water drops |
| | | | | Water separates to top |
| PE7h | 14.28 | 9.50 | 4.65 | Large emulsified water |
| | | | | drops; Water separates |
| | | | | to top |
| PE7i | 33.33 | 9.50 | 4.65 | Water separates to top |
| PE7j | 66.67 | 9.50 | 4.65 | Water separates to top |
| PE7k | 122.2 | 9.50 | 4.65 | Water separates to top |
| PE7l | 233.3 | 9.50 | 4.65 | Water separates to top |

TABLE 3-8
Compatibility of Liquid Adhesive Precursors
(PE8) with Deionized Water

| | Water | Total SP | H-Bonding SP | Observed Compatibility |
|---|---|---|---|---|
| | (%) | (cal/cm³)^{0.5} | (cal/cm³)^{0.5} | with Water |
| PE8a | 0.00 | 9.41 | 4.95 | — |
| PE8b | 0.503 | 9.41 | 4.95 | Single phase |
| PE8c | 1.266 | 9.41 | 4.95 | Emulsified water droplets |
| PE8d | 2.564 | 9.41 | 4.95 | Emulsified water droplets |
| PE8e | 5.102 | 9.41 | 4.95 | Emulsified water droplets |
| PE8f | 8.108 | 9.41 | 4.95 | Emulsified water droplets |
| PE8g | 11.11 | 9.41 | 4.95 | Large emulsified water |
| | | | | drops |
| PE8h | 14.28 | 9.41 | 4.95 | Water separates to top |
| PE8i | 33.33 | 9.41 | 4.95 | Water separates to top |
| PE8j | 66.67 | 9.41 | 4.95 | Water separates to top |
| PE8k | 122.2 | 9.41 | 4.95 | Water separates to top |
| PE8l | 233.3 | 9.41 | 4.95 | water separates to top |

TABLE 3-9
Compatibility of Liquid Adhesive Precursors
(PE9) with Deionized Water

| | Water | Total SP | H-Bonding SP | Observed Compatibility |
|---|---|---|---|---|
| | (%) | (cal/cm³)^{0.5} | (cal/cm³)^{0.5} | with Water |
| PE9a | 0.00 | 9.04 | 5.47 | — |
| PE9b | 0.503 | 9.04 | 5.47 | Single phase |
| PE9c | 1.266 | 9.04 | 5.47 | Single phase |
| PE9d | 2.564 | 9.04 | 5.47 | Single phase |
| PE9e | 5.102 | 9.04 | 5.47 | Emulsified water droplets |
| PE9f | 8.108 | 9.04 | 5.47 | Emulsified water droplets |
| PE9g | 11.11 | 9.04 | 5.47 | Emulsified water droplets |
| PE9h | 14.28 | 9.04 | 5.47 | Water separates to top |
| PE9i | 33.33 | 9.04 | 5.47 | Water separates to top |
| PE9j | 66.67 | 9.04 | 5.47 | Water separates to top |
| PE9k | 122.2 | 9.04 | 5.47 | Water separates to top |
| PE9l | 233.3 | 9.04 | 5.47 | Water separates to top |

TABLE 3-10
Compatibility of Liquid Adhesive Precursors
(PE10) with Deionized Water

| | | | H- | |
|---|---|---|---|---|
| | Water | Total SP | Bonding SP | Observed Compatibility |
| | (%) | (cal/cm³)^{0.5} | (cal/cm³)^{0.5} | with Water |
| PE10a | 0.00 | 8.82 | 5.94 | — |
| PE910b | 0.503 | 8.82 | 5.94 | Single phase |
| PE10c | 1.266 | 8.82 | 5.94 | Single phase |
| PE10d | 2.564 | 8.82 | 5.94 | Single phase |
| PE10e | 5.102 | 8.82 | 5.94 | Single phase |
| PE10f | 8.108 | 8.82 | 5.94 | Single phase |
| PE10g | 11.11 | 8.82 | 5.94 | Single phase |
| PE10h | 14.28 | 8.82 | 5.94 | Single phase |
| PE10i | 33.33 | 8.82 | 5.94 | Emulsified water droplets |
| | | | | with gel or precipitate |
| PE10j | 66.67 | 8.82 | 5.94 | Emulsified water droplets |
| | | | | with gel or precipitate |
| PE10k | 122.2 | 8.82 | 5.94 | Emulsified water droplets |
| | | | | with gel or precipitate |
| PE10l | 233.3 | 8.82 | 5.94 | Emulsified water droplets |
| | | | | with gel or precipitate |

TABLE 3-11
Compatibility of Liquid Adhesive Precursors
(PE11) with Deionized Water

| | | | H- | |
|---|---|---|---|---|
| | Water | Total SP | Bonding SP | Observed Compatibility |
| | (%) | (cal/cm³)^{0.5} | (cal/cm³)^{0.5} | with Water |
| PE11a | 0.00 | 9.28 | 5.06 | |
| PE11b | 0.503 | 9.28 | 5.06 | Single phase |
| PE11c | 1.266 | 9.28 | 5.06 | Single phase |
| PE11d | 2.564 | 9.28 | 5.06 | Single phase |
| PE11e | 5.102 | 9.28 | 5.06 | Small, emulsified water |
| | | | | droplets |
| PE11f | 8.108 | 9.28 | 5.06 | Emulsified water droplets |
| PE11g | 11.11 | 9.28 | 5.06 | Emulsified water droplets |
| PE11h | 14.28 | 9.28 | 5.06 | Emulsified water droplets |
| PE11i | 33.33 | 9.28 | 5.06 | Water separates to top |
| PE11j | 66.67 | 9.28 | 5.06 | Water separates to top |
| PE11k | 122.2 | 9.28 | 5.06 | Water separates to top |
| PE11l | 233.3 | 9.28 | 5.06 | Water separates to top |

TABLE 3-12
Compatibility of Liquid Adhesive Precursors
(PE12) with Deionized Water

| | | | H- | |
|---|---|---|---|---|
| | Water | Total SP | Bonding SP | Observed Compatibility |
| | (%) | (cal/cm³)^{0.5} | (cal/cm³)^{0.5} | with Water |
| PE12a | 0.00 | 9.21 | 5.26 | — |
| PE12b | 0.503 | 9.21 | 5.26 | Single phase |
| PE12c | 1.266 | 9.21 | 5.26 | Single phase |
| PE12d | 2.564 | 9.21 | 5.26 | Single phase |
| PE12e | 5.102 | 9.21 | 5.26 | Single phase |
| PE12f | 8.108 | 9.21 | 5.26 | Single phase |
| PE12g | 11.11 | 9.21 | 5.26 | Single phase |
| PE12h | 14.28 | 9.21 | 5.26 | Emulsified water droplets |
| PE12i | 33.33 | 9.21 | 5.26 | Water separates to top |
| PE12j | 66.67 | 9.21 | 5.26 | Water separates to top |
| PE12k | 122.2 | 9.21 | 5.26 | Water separates to top |
| PE12l | 233.3 | 9.21 | 5.26 | Water separates to top |

TABLE 3-13
Compatibility of Liquid Adhesive Precursors
(PE13) with Deionized Water

| | | | H- | |
|---|---|---|---|---|
| | Water | Total SP | Bonding SP | Observed Compatibility |
| | (%) | (cal/cm³)^{0.5} | (cal/cm³) | with Water |
| PE13a | 0.00 | 9.18 | 5.41 | — |
| PE13b | 0.503 | 9.18 | 5.41 | Single phase |
| PE13c | 1.266 | 9.18 | 5.41 | Single phase |
| PE13d | 2.564 | 9.18 | 5.41 | Single phase |
| PE13e | 5.102 | 9.18 | 5.41 | Single phase |
| PE13f | 8.108 | 9.18 | 5.41 | Single phase |
| PE13g | 11.11 | 9.18 | 5.41 | Single phase |
| PE13h | 14.28 | 9.18 | 5.41 | Emulsified water droplets |
| PE13i | 33.33 | 9.18 | 5.41 | Large, emulsified water |
| | | | | droplets |
| PE13j | 66.67 | 9.18 | 5.41 | Water separates to top |
| PE13k | 122.2 | 9.18 | 5.41 | Water separates to top |
| PE13l | 233.3 | 9.18 | 5.41 | Water separates to top |

TABLE 3-14
Compatibility of Liquid Adhesive Precursors
(PE14) with Deionized Water

| | | | H- | |
|---|---|---|---|---|
| | Water | Total SP | Bonding SP | Observed Compatibility |
| | (%) | (cal/cm³)^{0.5} | (cal/cm³)^{0.5} | with Water |
| PE14a | 0.00 | 8.90 | 5.81 | — |
| PE14b | 0.503 | 8.90 | 5.81 | Single phase |
| PE14c | 1.266 | 8.90 | 5.81 | Single phase |
| PE14d | 2.564 | 8.90 | 5.81 | Single phase |
| PE14e | 5.102 | 8.90 | 5.81 | Single phase |
| PE14f | 8.108 | 8.90 | 5.81 | Single phase |
| PE14g | 11.11 | 8.90 | 5.81 | Single phase |
| PE14h | 14.28 | 8.90 | 5.81 | Single phase |
| PE14i | 33.33 | 8.90 | 5.81 | Single phase |
| PE14j | 66.67 | 8.90 | 5.81 | Emulsified water droplets |
| PE14k | 122.2 | 8.90 | 5.81 | Large, emulsified water |
| | | | | droplets |
| PE14l | 233.3 | 8.90 | 5.81 | Large, emulsified water |
| | | | | droplets |

### Examples (Exs) and Comparative Examples (CEs)

After recording visual observations (above), each liquid, adhesive precursor solution was swirled by hand and 1-2 drops of the liquid was applied to a 1 mm FISHERBRAND plain, pre-cleaned microscope slide (CAT #12-550B, from Fischer Scientific, Hampton New Hampshire) with a disposable plastic pipette. Next, a piece of PET1 film, i.e. a film layer, was placed on the liquid drop with the primed side of the PET1 film contacting the liquid, forming a glass (substrate)-liquid, adhesive precuror-PET1 film layer laminate. Visual observations from this coating and lamination were recorded, see Tables 4-1 through 4-10. In some instances, the coating solution would phase separate during lamination as the surface area of the drop changed and was no longer exposed to an air interface.

Next, the glass-liquid, adhesive precuror-PET1 film layer laminate was exposed to UV radiation in order to cure the liquid, adhesive precursor, forming a glass (substrate)-cured adhesive layer-PET1 film layer laminate. The PET1 film was faced towards a CLEARSTONE TECH CF1000 LED UV processor, available from Clearstone Technologies, Inc., Hopkins, Minnesota. The distance between the laminate and the UV source was 2.75 inch (7 cm). The wavelength of the LED was 391 nm. The power was set to 100% and the exposure time was 20 sec.

Following cure, the PET1 film layer was stripped from the glass slides. Observations from this peeling operation were made and recorded see Tables 4-1 through 4-14. Note, in Tables 4-1 through 4-14, the phrase “Fully cured” means that the liquid, adhesive precursor had sufficient depth of cure and extent of cure to be removed cleanly from the glass substrate, i.e. there was no cured adhesive residue, liquid, adhesive precursor or water on the substrate surface. It is desirable for the cured adhesive layer to be remove cleanly from the glass substrate, leaving no residue (e.g. cured adhesive or uncured liquid, adhesive precursor) and to remain well adhered to the PET1 film layer. However, in some instances, the at least a portion of the cured adhesive layer remained on the glass substrate, or liquid water and/or liquid adhesive precursor remained on the glass microscope slide.

TABLE 4-1
Coating/Lamination and Peeling/Curing
Observations of PE1a-PE1l

| | | Water | Coating/ | |
|---|---|---|---|---|
| CE | PE1 | (%) | Lamination | Peeling/Curing |
| CE-1 | PE1a | 0.00 | Single phase | Clean peel/Fully Cured |
| CE-2 | PE1b | 0.503 | Single phase | Clean peel/Fully Cured |
| CE-3 | PE1c | 1.266 | Phase separated on | Peels/Water and/or PE1c |
| | | | glass slide | remains on glass |
| CE-4 | PE1d | 2.564 | Phase separated on | Peels/Water and/or PE1d |
| | | | glass slide | remains on glass |
| CE-5 | PE1e | 5.102 | Phase separated on | Peels/Water and/or PE1e |
| | | | glass slide, bubbles | remains on glass |
| CE-6 | PE1f | 8.108 | Phase separated on | Peels/Water and/or PE1f |
| | | | glass slide, bubbles | remains on glass |
| CE-7 | PE1g | 11.11 | Phase separated on | Peels/Water and/or PE1g |
| | | | glass slide, bubbles | remains on glass |
| CE-8 | PE1h | 14.28 | Phase separated on | Peels/Water and/or PE1h |
| | | | glass slide, bubbles | remains on glass |
| CE-9 | PE1i | 33.33 | Phase separated on | Peels/Water and/or PE1i |
| | | | glass slide, bubbles | remains on glass |
| CE-10 | PE1j | 66.67 | Phase separated on | Peels/Water and/or PE1j |
| | | | glass slide, bubbles | remains on glass |
| CE-11 | PE1k | 122.2 | Phase separated on | Peels/Water and/or PE1k |
| | | | glass slide, bubbles | remains on glass |
| CE-12 | PE1l | 233.3 | Phase separated on | Peels/Water and/or PE1l |
| | | | glass slide, bubbles | remains on glass |

TABLE 4-2
Coating/Lamination and Peeling/Curing
Observations of PE2a-PE2l

| Exam- | | Water | Coating/ | |
|---|---|---|---|---|
| ple | PE2 | (%) | Lamination | Peeling/Curing |
| Ex. 1 | PE2a | 0.00 | Single phase | Clean peel/Fully Cured |
| Ex. 2 | PE2b | 0.503 | Single phase | Clean peel/Fully Cured |
| Ex. 3 | PE2c | 1.266 | Single phase | Clean peel/Fully Cured |
| Ex. 4 | PE2d | 2.564 | Single phase | Clean peel/Fully Cured |
| Ex. 5 | PE2e | 5.102 | Phase separated on | Peels/Water and/or PE2e |
| | | | glass slide | remains on glass |
| Ex. 6 | PE2f | 8.108 | Phase separated on | Peels/Water and/or PE2f |
| | | | glass slide | remains on glass |
| Ex. 7 | PE2g | 11.11 | Phase separated on | Peels/Water and/or PE2g |
| | | | glass slide | remains on glass |
| Ex. 8 | PE2h | 14.28 | Phase separated on | Peels/Water and/or PE2h |
| | | | glass slide | remains on glass |
| Ex. 9 | PE2i | 33.33 | Phase separated on | Peels/Water and/or PE2i |
| | | | glass slide, bubbles | remains on glass |
| Ex. 10 | PE2j | 66.67 | Phase separated on | Peels/Water and/or PE2j |
| | | | glass slide, bubbles | remains on glass |
| Ex. 11 | PE2k | 122.2 | Phase separated on | Peels/Water and/or PE2k |
| | | | glass slide, bubbles | remains on glass |
| Ex. 12 | PE2l | 233.3 | Phase separated on | Peels/Water and/or PE2l |
| | | | glass slide, bubbles | remains on glass |

TABLE 4-3
Coating/Lamination and Peeling/Curing
Observations of PE3a-PE3l

| Exam- | | Water | Coating/ | |
|---|---|---|---|---|
| ple | PE3 | (%) | Lamination | Peeling/Curing |
| Ex. 13 | PE3a | 0.00 | Single phase | Clean peel/Fully Cured |
| Ex. 14 | PE3b | 0.503 | Single phase | Clean peel/Fully Cured |
| Ex. 15 | PE3c | 1.266 | Single phase | Clean peel/Fully Cured |
| Ex. 16 | PE3d | 2.564 | Single phase | Clean peel/Fully Cured |
| Ex. 17 | PE3e | 5.102 | Single phase | Clean peel/Fully Cured |
| Ex. 18 | PE3f | 8.108 | Phase separated on | Peels/Water and/or PE3f |
| | | | glass slide | remains on glass |
| Ex. 19 | PE3g | 11.11 | Phase separated on | Peels/Water and/or PE3g |
| | | | glass slide | remains on glass |
| Ex. 20 | PE3h | 14.28 | Phase separated on | Peels/Water and/or PE3h |
| | | | glass slide | remains on glass |
| Ex. 21 | PE3i | 33.33 | Phase separated on | Peels/Water and/or PE3i |
| | | | glass slide, bubbles | remains on glass |
| Ex. 22 | PE3j | 66.67 | Phase separated on | Peels/Water and/or PE3j |
| | | | glass slide, bubbles | remains on glass |
| Ex. 23 | PE3k | 122.2 | Phase separated on | Peels/Water and/or PE3k |
| | | | glass slide, bubbles | remains on glass |
| Ex. 24 | PE3l | 233.3 | Phase separated on | Peels/Water and/or PE2l |
| | | | glass slide, bubbles | remains on glass |

TABLE 4-4
Coating/Lamination and Peeling/Curing
Observations of PE4a-PE4l

| Exam- | | Water | Coating/ | |
|---|---|---|---|---|
| ple | PE4 | (%) | Lamination | Peeling/Curing |
| Ex. 25 | PE4a | 0.00 | Single phase | Clean peel/Fully Cured |
| Ex. 26 | PE4b | 0.503 | Single phase | Clean peel/Fully Cured |
| Ex. 27 | PE4c | 1.266 | Single phase | Clean peel/Fully Cured |
| Ex. 28 | PE4d | 2.564 | Single phase | Clean peel/Fully Cured |
| Ex. 29 | PE4e | 5.102 | Single phase | Clean peel/Fully Cured |
| Ex. 30 | PE4f | 8.108 | Single phase | Clean peel/Fully Cured |
| Ex. 31 | PE4g | 11.11 | PE4g is hazy on | Clean peel/Fully Cured |
| | | | glass slide | |
| Ex. 32 | PE4h | 14.28 | Phase separated on | Peels/Water and/or PE4h |
| | | | glass slide, bubbles | remains on glass |
| Ex. 33 | PE4i | 33.33 | Phase separated on | Peels/Water and/or PE4i |
| | | | glass slide, bubbles | remains on glass |
| Ex. 34 | PE4j | 66.67 | Phase separated on | Peels/Water and/or PE4j |
| | | | glass slide, bubbles | remains on glass |
| Ex. 35 | PE4k | 122.2 | Phase separated on | Peels/Water and/or PE4k |
| | | | glass slide, bubbles | remains on glass |
| Ex. 36 | PE4l | 233.3 | Phase separated on | Peels/Water and/or PE4l |
| | | | glass slide, bubbles | remains on glass |

TABLE 4-5
Coating/Lamination and Peeling/Curing
Observations of PE5a-PE5l

| Exam- | | Water | Coating/ | |
|---|---|---|---|---|
| ple | PE5 | (%) | Lamination | Peeling/Curing |
| Ex. 37 | PE5a | 0.00 | Single phase | Clean peel/Fully Cured |
| Ex. 38 | PE5b | 0.503 | Single phase | Clean peel/Fully Cured |
| Ex. 39 | PE5c | 1.266 | Single phase | Clean peel/Fully Cured |
| Ex. 40 | PE5d | 2.564 | Single phase | Clean peel/Fully Cured |
| Ex. 41 | PE5e | 5.102 | Single phase | Clean peel/Fully Cured |
| Ex. 42 | PE5f | 8.108 | Single phase | Clean peel/Fully Cured |
| Ex. 43 | PE5g | 11.11 | Single phase | Clean peel/Fully Cured |
| Ex. 44 | PE5h | 14.28 | Single phase | Clean peel/Fully Cured |
| Ex. 45 | PE5i | 33.33 | Single phase | Clean peel/Fully Cured |
| Ex. 46 | PE5j | 66.67 | Single phase | Clean peel/ Fully Cured |
| Ex. 47 | PE5k | 122.2 | Phase separated on | Peels/Water and/or PE5k |
| | | | glass slide | remains on glass |
| Ex. 48 | PE5l | 233.3 | Phase separated on | Peels/Water and/or PE5l |
| | | | glass slide | remains on glass |

TABLE 4-6
Coating/Lamination and Peeling/Curing
Observations of PE6a-PE6l

| Exam- | | Water | Coating/ | |
|---|---|---|---|---|
| ple | PE6 | (%) | Lamination | Peeling/Curing |
| Ex. 49 | PE6a | 0.00 | Single phase | Clean peel/Fully Cured |
| Ex. 50 | PE6b | 0.503 | Single phase | Clean peel/ Fully Cured |
| Ex. 51 | PE6c | 1.266 | Single phase | Clean peel/Fully Cured |
| Ex. 52 | PE6d | 2.564 | Single phase | Clean peel/Fully Cured |
| Ex. 53 | PE6e | 5.102 | Single phase | Clean peel/Fully Cured |
| Ex. 54 | PE6f | 8.108 | Single phase | Clean peel/Fully Cured |
| Ex. 55 | PE6g | 11.11 | Single phase | Clean peel/Fully Cured |
| Ex. 56 | PE6h | 14.28 | Single phase | Clean peel/Fully Cured |
| Ex. 57 | PE6i | 33.33 | Single phase | Clean peel/Fully Cured |
| Ex. 58 | PE6j | 66.67 | Single phase | Clean peel/Fully Cured |
| Ex. 59 | PE6k | 122.2 | Phase separated on | Clean peel/Fully Cured |
| | | | glass slide | |
| Ex. 60 | PE6l | 233.3 | Phase separated on | Peels/Water and/or PE6l |
| | | | glass slide | remains on glass |

TABLE 4-7
Coating/Lamination and Peeling/Curing
Observations of PE7a-PE7l

| Exam- | | Water | Coating/ | |
|---|---|---|---|---|
| ple | PE7 | (%) | Lamination | Peeling/Curing |
| Ex. 61 | PE7a | 0.00 | Single phase | Cured coating does not |
| | | | | peel off glass slide/ |
| | | | | Fully Cured |
| Ex. 62 | PE7b | 0.503 | Phase separated on | Does not peel off glass |
| | | | glass slide | slide/Water and/or PE7b |
| | | | | remains on glass |
| Ex. 63 | PE7c | 1.266 | Phase separated on | Does not peel off glass |
| | | | glass slide | slide/Water and/or PE7c |
| | | | | remains on glass |
| Ex. 64 | PE7d | 2.564 | Phase separated on | Does not peel off glass |
| | | | glass slide | slide/Water and/or PE7d |
| | | | | remains on glass |
| Ex. 65 | PE7e | 5.102 | Phase separated on | Does not peel off glass |
| | | | glass slide | slide/Water and/or PE7e |
| | | | | remains on glass |
| Ex. 66 | PE7f | 8.108 | Phase separated on | Peels/Water and/or PE7f |
| | | | glass slide | remains on glass |
| Ex. 67 | PE7g | 11.11 | Phase separated on | Peels/Water and/or PE7g |
| | | | glass slide | remains on glass |
| Ex. 68 | PE7h | 14.28 | Phase separated on | Peels/Water and/or PE7h |
| | | | glass slide | remains on glass |
| Ex. 69 | PE7i | 33.33 | Phase separated on | Peels/Water and/or PE7i |
| | | | glass slide, bubbles | remains on glass |
| Ex. 70 | PE7j | 66.67 | Phase separated on | Peels/Water and/or PE7j |
| | | | glass slide, bubbles | remains on glass |
| Ex. 71 | PE7k | 122.2 | Phase separated on | Peels/Water and/or PE7k |
| | | | glass slide, bubbles | remains on glass |
| Ex. 72 | PE7l | 233.3 | Phase separated on | Peels/Water and/or PE7l |
| | | | glass slide, bubbles | remains on glass |

TABLE 4-8
Coating/Lamination and Peeling/Curing
Observations of PE8a-PE8l

| Exam- | | Water | Coating/ | |
|---|---|---|---|---|
| ple | PE8 | (%) | Lamination | Peeling/Curing |
| Ex. 73 | PE8a | 0.00 | Single phase | Cured coating does not |
| | | | | peel off glass slide/ |
| | | | | Fully Cured |
| Ex. 74 | PE8b | 0.503 | Single phase | Cured coating does not |
| | | | | peel off glass slide/ |
| | | | | Fully Cured |
| Ex. 75 | PE8c | 1.266 | Phase separated on | Does not peel off glass |
| | | | glass slide | slide/Water and/or PE8c |
| | | | | remains on glass |
| Ex. 76 | PE8d | 2.564 | Phase separated on | Does not peel off glass |
| | | | glass slide | slide/Water and/or PE8d |
| | | | | remains on glass |
| Ex. 77 | PE8e | 5.102 | Phase separated on | Peels/Water and/or PE8f |
| | | | glass slide | remains on glass |
| Ex. 78 | PE8f | 8.108 | Phase separated on | Peels/Water and/or PE8f |
| | | | glass slide | remains on glass |
| Ex. 79 | PE8g | 11.11 | Phase separated on | Peels/Water and/or PE8g |
| | | | glass slide | remains on glass |
| Ex. 80 | PE8h | 14.28 | Phase separated on | Peels/Water and/or PE8h |
| | | | glass slide | remains on glass |
| Ex. 81 | PE8i | 33.33 | Phase separated on | Peels/Water and/or PE8i |
| | | | glass slide, bubbles | remains on glass |
| Ex. 82 | PE8j | 66.67 | Phase separated on | Peels/Water and/or PE8j |
| | | | glass slide, bubbles | remains on glass |
| Ex. 83 | PE8k | 122.2 | Phase separated on | Peels/Water and/or PE8k |
| | | | glass slide, bubbles | remains on glass |
| Ex. 84 | PE8l | 233.3 | Phase separated on | Peels/Water and/or PE8l |
| | | | glass slide, bubbles | remains on glass |

TABLE 4-9
Coating/Lamination and Peeling/Curing
Observations of PE9a-PE9l

| Exam- | | Water | Coating/ | |
|---|---|---|---|---|
| ple | PE9 | (%) | Lamination | Peeling/Curing |
| Ex. 85 | PE9a | 0.00 | Single phase | Cured coating does not |
| | | | | peel off glass slide/ |
| | | | | Fully Cured |
| Ex. 86 | PE9b | 0.503 | Single phase | Clean peel/Fully Cured |
| Ex. 87 | PE9c | 1.266 | Single phase | Clean peel/Fully Cured |
| Ex. 88 | PE9d | 2.564 | Single phase | Clean peel/Fully Cured |
| Ex. 89 | PE9e | 5.102 | Single phase | Clean peel/Fully Cured |
| Ex. 90 | PE9f | 8.108 | Phase separated on | Peels/Water and/or PE8f |
| | | | glass slide/hazy | remains on glass |
| Ex. 91 | PE9g | 11.11 | Phase separated on | Peels/Water and/or PE9g |
| | | | glass slide/hazy | remains on glass |
| Ex. 92 | PE9h | 14.28 | Phase separated on | Peels/Water and/or PE9h |
| | | | glass slide | remains on glass |
| Ex. 93 | PE9i | 33.33 | Phase separated on | Peels/Water and/or PE9i |
| | | | glass slide | remains on glass |
| Ex. 94 | PE9j | 66.67 | Phase separated on | Peels/Water and/or PE9j |
| | | | glass slide | remains on glass |
| Ex. 95 | PE9k | 122.2 | Phase separated on | Peels/Water and/or PE9k |
| | | | glass slide, bubbles | remains on glass |
| Ex. 96 | PE9l | 233.3 | Phase separated on | Peels/Water and/or PE9l |
| | | | glass slide, bubbles | remains on glass |

TABLE 4-10
Coating/Lamination and Peeling/Curing
Observations of PE10a-PE10l

| Exam- | | Water | Coating/ | |
|---|---|---|---|---|
| ple | PE10 | (%) | Lamination | Peeling/Curing |
| Ex. 97 | PE10a | 0.00 | Single phase | Clean peel/Fully Cured |
| Ex. 98 | PE10b | 0.503 | Single phase | Clean peel/Fully Cured |
| Ex. 99 | PE10c | 1.266 | Single phase | Clean peel/Fully Cured |
| Ex. 100 | PE10d | 2.564 | Single phase | Clean peel/Fully Cured |
| Ex. 101 | PE10e | 5.102 | Single phase | Clean peel/Fully Cured |
| Ex. 102 | PE10f | 8.108 | Single phase | Clean peel/Fully Cured |
| Ex. 103 | PE10g | 11.11 | Single phase | Clean peel/Fully Cured |
| Ex. 104 | PE10h | 14.28 | Single phase | Clean peel/Fully Cured |
| Ex. 105 | PE10i | 33.33 | Single phase | Clean peel/Fully Cured |
| Ex. 106 | PE10j | 66.67 | Single phase | Clean peel/Fully Cured |
| Ex. 107 | PE10k | 122.2 | Single phase | Peels/Water and/or |
| | | | | PE10k remains on glass |
| Ex. 108 | PE10l | 233.3 | Phase separated | Peels/Water and/or |
| | | | on glass slide | PE10l remains on glass |

TABLE 4-11
Coating/Lamination and Peeling/Curing
Observations of PE11a-PE11l

| Exam- | | Water | Coating/ | |
|---|---|---|---|---|
| ple | PE11 | (%) | Lamination | Peeling/Curing |
| Ex. 109 | PE11a | 0.00 | Single phase | Clean peel/Fully Cured |
| Ex. 110 | PE11b | 0.503 | Single phase | Clean peel/Fully Cured |
| Ex. 111 | PE11c | 1.266 | Single phase | Clean peel/Fully Cured |
| Ex. 112 | PE11d | 2.564 | Single phase | Clean peel/Fully Cured |
| Ex. 113 | PE11e | 5.102 | PE11e is hazy on | Peels/Water and/or |
| | | | glass slide | PE11e remains on glass |
| Ex. 114 | PE11f | 8.108 | Phase separated | Peels/Water and/or |
| | | | on glass slide | PE11f remains on glass |
| Ex. 115 | PE11g | 11.11 | Phase separated | Peels/Water and/or |
| | | | on glass slide | PE11g remains on glass |
| Ex. 116 | PE11h | 14.28 | Phase separated | Peels/Water and/or |
| | | | on glass slide | PE11h remains on glass |
| Ex. 117 | PE11i | 33.33 | Phase separated | Peels/Water and/or |
| | | | on glass slide | PE11i remains on glass |
| Ex. 118 | PE11j | 66.67 | Phase separated | Peels/Water and/or |
| | | | on glass slide | PE11j remains on glass |
| Ex. 119 | PE11k | 122.2 | Phase separated | Peels/Water and/or |
| | | | on glass slide | PE11k remains on glass |
| Ex. 120 | PE11l | 233.3 | Phase separated | Peels/Water and/or |
| | | | on glass slide | PE11l remains on glass |

TABLE 4-12
Coating/Lamination and Peeling/Curing
Observations of PE12a-PE12l

| Exam- | | Water | Coating/ | |
|---|---|---|---|---|
| ple | PE12 | (%) | Lamination | Peeling/Curing |
| Ex. 121 | PE12a | 0.00 | Single phase | Clean peel/Fully Cured |
| Ex. 122 | PE12b | 0.503 | Single phase | Clean peel/Fully Cured |
| Ex. 123 | PE12c | 1.266 | Single phase | Clean peel/Fully Cured |
| Ex. 124 | PE12d | 2.564 | Single phase | Clean peel/Fully Cured |
| Ex. 125 | PE12e | 5.102 | Single phase | Clean peel/Fully Cured |
| Ex. 126 | PE12f | 8.108 | Single phase | Clean peel/Fully Cured |
| Ex. 127 | PE12g | 11.11 | PE12g is hazy on | Clean peel/Fully Cured |
| | | | glass slide | |
| Ex. 128 | PE12h | 14.28 | PE12h is hazy on | Peels/Water and/or |
| | | | glass slide | PE12h remains on glass |
| Ex. 129 | PE12i | 33.33 | Phase separated | Peels/Water and/or |
| | | | on glass slide | PE12i remains on glass |
| Ex. 130 | PE12j | 66.67 | Phase separated | Peels/Water and/or |
| | | | on glass slide | PE12j remains on glass |
| Ex. 131 | PE12k | 122.2 | Phase separated | Peels/Water and/or |
| | | | on glass slide | PE12k remains on glass |
| Ex. 132 | PE12l | 233.3 | Phase separated | Peels/Water and/or |
| | | | on glass slide | PE12l remains on glass |

TABLE 4-13
Coating/Lamination and Peeling/Curing
Observations of PE13a-PE13l

| Exam- | | Water | Coating/ | |
|---|---|---|---|---|
| ple | PE13 | (%) | Lamination | Peeling/Curing |
| Ex. 133 | PE13a | 0.00 | Single phase | Clean peel/Fully Cured |
| Ex. 134 | PE13b | 0.503 | Single phase | Clean peel/Fully Cured |
| Ex. 135 | PE13c | 1.266 | Single phase | Clean peel/Fully Cured |
| Ex. 136 | PE13d | 2.564 | Single phase | Clean peel/Fully Cured |
| Ex. 137 | PE13e | 5.102 | Single phase | Clean peel/Fully Cured |
| Ex. 138 | PE13f | 8.108 | Single phase | Clean peel/Fully Cured |
| Ex. 139 | PE13g | 11.11 | Single phase | Clean peel/Fully Cured |
| Ex. 140 | PE13h | 14.28 | PE13h is hazy on | Peels/Water and/or |
| | | | glass slide | PE13h remains on glass |
| Ex. 141 | PE13i | 33.33 | Phase separated | Peels/Water and/or |
| | | | on glass slide | PE13i remains on glass |
| Ex. 142 | PE13j | 66.67 | Phase separated | Peels/Water and/or |
| | | | on glass slide | PE13j remains on glass |
| Ex. 143 | PE13k | 122.2 | Phase separated | Peels/Water and/or |
| | | | on glass slide | PE13k remains on glass |
| Ex. 144 | PE13l | 233.3 | Phase separated | Peels/Water and/or |
| | | | on glass slide | PE13l remains on glass |

TABLE 4-14
Coating/Lamination and Peeling/Curing
Observations of PE14a-PE14l

| Exam- | | Water | Coating/ | |
|---|---|---|---|---|
| ple | PE14 | (%) | Lamination | Peeling/Curing |
| Ex. 145 | PE14a | 0.00 | Single phase | Clean peel/Fully Cured |
| Ex. 146 | PE14b | 0.503 | Single phase | Clean peel/Fully Cured |
| Ex. 147 | PE14c | 1.266 | Single phase | Clean peel/Fully Cured |
| Ex. 148 | PE14d | 2.564 | Single phase | Clean peel/Fully Cured |
| Ex. 149 | PE14e | 5.102 | Single phase | Clean peel/Fully Cured |
| Ex. 150 | PE14f | 8.108 | Single phase | Clean peel/Fully Cured |
| Ex. 151 | PE14g | 11.11 | Single phase | Clean peel/Fully Cured |
| Ex. 152 | PE14h | 14.28 | Single phase | Clean peel/Fully Cured |
| Ex. 153 | PE14i | 33.33 | Single phase | Clean peel/Fully Cured |
| Ex. 154 | PE14j | 66.67 | PE14j is hazy on | Clean peel/Fully Cured |
| | | | glass slide | |
| Ex. 155 | PE14k | 122.2 | Phase separated | Peels/Water and/or |
| | | | on glass slide | PE14k remains on glass |
| Ex. 156 | PE14l | 233.3 | Phase separated | Peels/Water and/or |
| | | | on glass slide | PE14l remains on glass |

### Examples 157 Through 163: Substrate Cleaning Experiments

UV curable, liquid, adhesive precursors were prepared according to the Table 5, below. Next, a nanoparticle dispersion was prepared by diluting D9228 in a 6.5:1 volume ratio with deionized water (6.5 parts water, 1 part D9228). The nanoparticle dispersion was set to moderate agitation on a magnetic stir plate. A small, 2.5 cm×2.5 cm, piece of SI WAFER1 was immersed in the nanoparticle dispersion while stirring for 1 min. During this process nanoparticles deposited onto to the surface of SI WAFER1. SI WAFER1 was then removed from the dispersion and rinsed with deionized water and, optionally, dried with an air gun. Using a pipette, a UV-curable liquid, adhesive precursors, per Table 5, was deposited onto the surface of the SI WAFER1. A piece of PET1 film was then laid upon the deposited precursor solution, forming a laminate. The laminate was then placed under a UV LED radiation source, the PET1 film directly facing the radiation source. The working distance between the laminate and the UV LED was 2.75 in (7 cm). The 391 nm UV LED source was from the CLEARSTONE TECH CF1000 processor, as previously described. The output power was set to 100%. The laminate was exposed to UV radiation for 20 seconds, forming a laminate with a cured adhesive layer (wafer substrate-cured adhesive layer-PET1 film layer). Next, the PET1 film and the cured adhesive layer with entrapped nanoparticles was peeled from the surface of the silicon wafer. SEM analysis was performed in order to approximate the % Removal of nanoparticles from the surface of the silicon wafer substrate, i.e. the percentage of the surface area of the wafer substrate cleaned of particles, in the region of the substrate surface in contact with the cured adhesive layer. SEM of Examples 157-161 was conducted on a Hitachi SU8230 field emission scanning electron microscope with an accelerating voltage of 3.0 kV at a working distance of 4 mm, after sputter coating the substrates with Ir to make them conductive. SEM of Examples 162 and 163 was conducted on a JEOL JSM 7600F field emission scanning electron microscope with an accelerating voltage of 15.0 kV at a working distance of 9 mm, after sputter coating the substrates with Au—Pd to make them conductive. Comparisons between surfaces contaminated by slurry particles and then after cleaning were made via SEM micrographs. This was accomplished by comparing the particle-deposited surface areas and the corresponding areas cleaned by removing the cured adhesive layer/film layer. Results are shown in Table 6. Note, results reported on a “Wet Substrate” were analyzed after the deionized water rinse (no drying).

TABLE 5
Liquid, Adhesive Precursor Compositions (values in wt. %)

| | Ex. | Ex. | Ex. | Ex. | Ex. | Ex. | Ex. |
|---|---|---|---|---|---|---|---|
| | 157 | 158 | 159 | 160 | 161 | 162 | 163 |
| SR351 | 98 | — | — | — | — | — | — |
| SR499 | — | 98 | — | — | — | — | — |
| SR502 | — | — | 98 | — | — | — | — |
| SR9035 | — | — | — | 98 | — | 99.9 | 58.8 |
| SR415 | — | — | — | — | 98 | — | — |
| Water | — | — | — | — | — | — | 40 |
| IRG819 | 2 | 2 | 2 | 2 | 2 | — | — |
| IRG2959 | — | — | — | — | — | 0.1 | 1.2 |

TABLE 6
Wafer Substrate Cleaning Results

| | % Particles | % Particles |
|---|---|---|
| | Removed | Removed |
| Example | (Dry Substrate) | (Wet Substrate) |
| Ex. 157 | — | >95 |
| Ex. 158 | — | >95 |
| Ex. 159 | >95 | >85 |
| Ex. 160 | — | >95 |
| Ex. 161 | >95 | >95 |
| Ex. 162 | >95 | >95 |
| Ex. 163 | >90 | — |

### Example 164: Cleaning of a Polished Wafer Surface

A nanoparticle dispersion was prepared by diluting D9228 in a 6.5:1 volume ratio with deionized water (6.5 parts water, 1 part D9228). The nanoparticle dispersion was set to moderate agitation on a magnetic stir plate. Several SI Wafer2 were polished using a MR665LP pad available from 3M Company, St. Paul, Minnesota. A 9 inch (23 cm) diameter coupon was cut out of a 30.5 inch (77.5 cm) diameter pad and installed on the platen of a benchtop CP4 polisher available from Bruker Tribology and Mechanical testing, San Jose, Ca. After installing the pad, a 15-min pad surface cleaning under 4 lbs (17.8 N) down force was performed with a PB33A brush available from 3M Company, in lieu of the conventional pad break-in process. Each wafer was polished for a duration of 1 min with D9228 nanoparticle dispersion supplied at a flow rate of 100 mL/min. The polishing pressure was 4 psi (27.6 kPa). The platen and head RPM's were set to 57 and 63 respectively. An Ex-situ pad cleaning was also conducted with the brush before each wafer run for a period of 15 sec at 3 lbs (13.3) downforce.

A UV curable, liquid, adhesive precursors was prepared from SR9036/NPO-L at a 99/1 wt./wt. ratio. Using a pipette, the UV-curable liquid, adhesive precursor, was deposited onto the polished surface of a SI WAFER2 to approximately form a 1 inch (2.5 cm) circle. A piece of PET1 film was then laid upon the deposited precursor solution, forming a laminate. The laminate was then placed under a UV LED radiation source, the PET1 film directly facing the radiation source. The working distance between the laminate and the UV LED was 2.75 in (7 cm). The 391 nm UV LED source was from the CLEARSTONE TECH CF1000 processor, as previously described. The output power was set to 100%. The laminate was exposed to UV radiation for 20 seconds, forming a laminate with a cured adhesive layer (wafer substrate-cured adhesive layer-PET1 film layer). Next, the PET1 film and the cured adhesive layer with entrapped nanoparticle contaminant was peeled from the surface of the silicon wafer. SEM analysis was performed in order to approximate the % Removal of nanoparticles from the surface of the silicon wafer substrate, i.e. the percentage of the surface area of the wafer substrate cleaned of particles, in the region of the substrate surface in contact with the cured adhesive layer. SEM of Example 116 was conducted on a JEOL JSM 7600F field emission scanning electron microscope with an accelerating voltage of 15.0 kV at a working distance of 9 mm, after sputter coating the substrates with Au—Pd to make them conductive. Comparisons between polish-contaminated surfaces and then after cleaning were made via SEM micrographs. This was accomplished by comparing the particle-deposited surface areas and the corresponding areas cleaned by removing the cured adhesive layer/film layer. Results indicate that, after being cleaned as described, greater than 95% of the particulate contaminate was removed from both a polished wafer surface that was cleaned immediately after polishing while it was still wet and from a polished wafer surface that was air-dried, post polish.

What is claimed is:

1. A laminate comprising:
a substrate having a first surface including a particulate contaminant disposed on the first surface;
a liquid, adhesive precursor in contact with the first surface of the substrate and the particulate contaminant, wherein the liquid, adhesive precursor is capable of being cured by actinic radiation and;
a film layer in contact with the liquid, adhesive precursor, wherein the liquid, adhesive precursor has at least one of (i) a total solubility parameter of no greater than 9.20 (cal/cm³)^{0.5} and (ii) a hydrogen bonding component solubility parameter of greater than 4.50 (cal/cm³)^{0.5}.

2. The laminate of claim 1, wherein the liquid, adhesive precursor is capable of absorbing between 0.5 wt. % and 125 wt. % of a polar solvent, based on the weight of the liquid, adhesive precursor, while maintaining its ability to be cured by actinic radiation.

3. The laminate of claim 2, wherein the polar solvent includes water, methanol, ethanol, propanol, isopropanol and combinations thereof.

4. The laminate of claim 1, wherein the liquid, adhesive precursor is a single-phase solution.

5. The laminate of claim 1, wherein the liquid, adhesive precursor includes polar (meth)acrylate.

6. The laminate of claim 1, wherein the substrate is semiconductor wafer, a plate, a roll, wafer processing equipment, precision lenses, optical devices and films.

7. A laminate comprising
a substrate having a first surface including a particulate contaminant disposed on the first surface;
a cured adhesive layer having a first and a second major surface, wherein the first major surface of the cured adhesive layer is in contact with the first surface of the substrate and the particulate contaminant, wherein the cured adhesive layer includes between 0.5 wt. % and 125 wt. % of a polar solvent, based on the weight of the cured adhesive layer excluding the polar solvent, and;
a film layer in contact with the second major surface of the cured adhesive layer, wherein the cured adhesive layer is the reaction product of a liquid, adhesive precursor capable of being cured by actinic radiation and having at least one of (i) a total solubility parameter of no greater than 9.20 (cal/cm³)^{0.5} and (ii) a hydrogen bonding component solubility parameter of greater than 4.50 (cal/cm³)^{0.5}.

8. The laminate of claim 7, wherein the cured adhesive layer includes between 2 wt. % and 125 wt. % of a polar solvent, based on the weight of the cured adhesive layer excluding the polar solvent.

9. The laminate of claim 7, wherein the cured adhesive layer includes the reaction product of a polar (meth)acrylate.

10. A method of cleaning a substrate surface comprising:
providing a substrate having a first surface including a particulate contaminant and a polar solvent disposed on the first surface;
coating at least a portion of the first surface, including the particulate contaminant and the polar solvent, with a liquid, adhesive precursor;
disposing a film layer on the liquid, adhesive precursor;
providing actinic radiation through the film layer, thereby curing the liquid, adhesive precursor and forming a cured adhesive layer, which entraps the particulate contaminant and;
removing the film layer, cured adhesive layer and at least a portion of particulate contaminant from the first surface.
